(19) United States
(12) Patent Application Publication
(10) Pub. No.: US 2024/0158691 A1
(43) Pub. Date: May 16, 2024

(54) QUANTUM DOT, QUANTUM DOT LAYER, LIGHT-EMITTING ELEMENT, AND SOLAR CELL

(71) Applicant: SHARP KABUSHIKI KAISHA, Sakai City, Osaka (JP)

(72) Inventors: Ryo KITAMURA, Sakai City, Osaka (JP); YOSHIHIRO UETA, Sakai City, Osaka (JP)

(21) Appl. No.: 18/281,151

(22) PCT Filed: Mar. 12, 2021
(86) PCT No.: PCT/JP2021/010042

§ 371 Date: Sep. 8, 2023

(51) Int. Cl. C09K 11/02; C09K 11/60; C09K 11/61; B82Y 20/00; H10K 30/50; H10K 50/115

(52) U.S. Cl. CPC C09K 11/025; C09K 11/605; C09K 11/616; B82Y 20/00; H10K 30/50; H10K 50/115

(57) ABSTRACT

A quantum dot according to the present application includes a surface including polar planes accounting for an area percentage of 70% or more, or a surface including non-polar planes accounting for an area percentage of 70% or more.

### TECHNICAL FIELD

The disclosure relates to a quantum dot, a quantum dot layer, a light-emitting element, and a solar cell.

### BACKGROUND ART

A technique of protecting a polar plane of a quantum dot with polar ligands and a non-polar plane of a quantum dot with neutral ligands is known.

For example, PTL 1 discloses a configuration in which a polar plane of a quantum dot is protected by ligands bonded thereto, and a non-polar plane of a quantum dot is protected by other ligands bonded thereto. For example, PTL 2 discloses a configuration in which a halide protects a polar plane of a quantum dot and an alkali metal protects a non-polar plane of a quantum dot.

NPLs 1 and 2 each disclose a procedure for producing a quantum dot.

### CITATION LIST

### Patent Literature

PTL 1: CN 110305656 A
PTL 2: WO 2019/218060 A1

### Non Patent Literature

NPL 1: Nat. Mater. 2014, 13, 822
NPL 2: Angew. Chem. Int. Ed. 2009, 48, 6861 to 6864

### SUMMARY

### Technical Problem

Methods of realizing known techniques such as in PTLs 1 and 2 described above include a method of protecting a quantum dot with polar ligands and neutral ligands mixed together, and a method of protecting a quantum dot with one of polar ligands and neutral ligands and subsequently performing a ligand exchange.

However, both of these methods are problematic in that a manufacturing efficiency of surface-protected quantum dots is low due to an increase in a number of processes, difficulties in controlling a ligand amount, and the like. Further, the problem arises that the quantum dot has low luminous efficiency and low reliability.

An object of an aspect of the disclosure is to improve a manufacturing efficiency, a luminous efficiency, and a reliability of a surface-protected quantum dot.

### Solution to Problem

To solve the problems described above, a quantum dot according to an aspect of the disclosure includes a surface including polar planes accounting for an area percentage of 70% or more, or a surface including non-polar planes accounting for an area percentage of 70% or more.

### Advantageous Effects of Disclosure

According to an aspect of the disclosure, a manufacturing efficiency of a surface-protected quantum dot can be improved.

### BRIEF DESCRIPTION OF DRAWINGS

FIG. 1 is a cross-sectional view schematically illustrating a light-emitting element according to a first embodiment of the disclosure.

FIG. 2 is a perspective view illustrating a structure of an example of a quantum dot according to the first embodiment of the disclosure.

FIG. 3 is a view illustrating a plane orientation of each crystal plane of the quantum dot illustrated in FIG. 2.

FIG. 4 is a view illustrating the plane orientation of each crystal plane of the quantum dot illustrated in FIG. 2.

FIG. 5 is a schematic view schematically illustrating a surface of the quantum dot illustrated in FIG. 2 and polar ligands protecting the surface.

FIG. 6 is a perspective view illustrating a structure of a modified example of the quantum dot according to the first embodiment of the disclosure.

FIG. 7 is a perspective view illustrating the structure of the modified example of the quantum dot according to the first embodiment of the disclosure.

FIG. 8 is a cross-sectional view schematically illustrating a solar cell including a photoelectric conversion layer including the quantum dot according to the first embodiment of the disclosure.

FIG. 9 is a perspective view illustrating a structure of an example of a quantum dot according to a second embodiment of the disclosure.

FIG. 10 is a perspective view illustrating a structure of an example of a quantum dot according to a third embodiment of the disclosure.

FIG. 11 is a view illustrating a plane orientation of each crystal plane of the quantum dot illustrated in FIG. 10.

FIG. 12 is a view illustrating a manufacturing method of the example of the quantum dot illustrated in FIG. 10.

FIG. 13 is a view illustrating the manufacturing method of the example of the quantum dot illustrated in FIG. 10.

FIG. 14 is a perspective view illustrating a structure of a modified example of the quantum dot according to the third embodiment of the disclosure.

FIG. 15 is a perspective view illustrating a structure of an example of a quantum dot according to a fourth embodiment of the disclosure.

FIG. 16 is a schematic view schematically illustrating a surface of the quantum dot illustrated in FIG. 15 and polar ligands protecting the surface.

FIG. 17 is a perspective view illustrating a structure of an example of a quantum dot according to a fifth embodiment of the disclosure.

FIG. 18 is a perspective view illustrating a structure of an example of a quantum dot according to a sixth embodiment of the disclosure.

FIG. 19 is a view illustrating a plane orientation of each crystal plane of the quantum dot illustrated in FIG. 18.

FIG. 20 is a perspective view illustrating a modified example of the quantum dot according to the sixth embodiment of the disclosure.

FIG. 21 is a view illustrating a plane orientation of each crystal plane of the quantum dot illustrated in FIG. 20.

FIG. 22 is a perspective view illustrating a structure of a modified example of the quantum dot according to the sixth embodiment of the disclosure.

FIG. 23 is a transverse cross-sectional view illustrating a plane orientation of each crystal plane of the quantum dot illustrated in FIG. 22.

### DESCRIPTION OF EMBODIMENTS

### First Embodiment

FIG. 1 is a cross-sectional view schematically illustrating a light-emitting element 5 according to a first embodiment of the disclosure. The light-emitting element (light-emitting element) 5 is a top-emission element having a conventional structure, and includes an anode 51, a hole injection layer 52, a hole transport layer 53, a light-emitting layer 54 (quantum dot layer), an electron transport layer 55, and a cathode 56.

Each layer forming the light-emitting element 5 can be prepared by film formation and patterning, such as colloidal solution application, coating and baking, sputtering using a metal mask, photolithography, resin filling, ashing, and dry/wet etching.

### Anode

The anode 51 is an electrode member including a material having electrical conductivity. In a case in which the light-emitting element 5 is a top-emission element having a conventional structure, the anode 51 is preferably a reflective electrode from the viewpoint of improving an extraction efficiency. When the anode 51 is a reflective electrode, the anode 51 may be made of, for example, Al, Ag, or an alloy thereof. However, the anode 51 is not limited thereto, and may be made of a transparent conductive material. In this case, the anode 51 preferably includes indium tin oxide (ITO) in consideration of level alignment with the hole injection layer 52 described below. The anode 51 may be prepared by forming a film of each material by sputtering. A layer thickness of the anode 51 is, for example, 100 nm or less. Alternatively, the anode 51 may be formed by providing a reflective layer made of Al or Ag in a lower layer underlying a conductive layer made of ITO with an insulating layer made of polyimide or the like interposed therebetween. In this case, a contact hole for connecting the ITO that is the conductive layer to a thin film transistor (TFT) may be formed in the insulating layer and the reflective layer by photolithography.

### Hole Injection Layer

The hole injection layer 52 is a layer including a material with hole injecting properties and having a function of increasing an efficiency of hole injection from the anode electrode to the hole transport layer 53 described below. When an organic material is used for the hole injection layer 52, the organic material is preferably PEDOT having a HOMO level that aligns with a work function of the anode 51. The hole injection layer 52 may be prepared by, for example, applying a coating material including PEDOT and subsequently curing the PEDOT at about 150° C.

From the viewpoint of improving a long-term reliability of the light-emitting element 5, the hole injection layer 52 is preferably made of an inorganic substance. The inorganic material of the hole injection layer 52 may be an inorganic substance typically used for the hole injection layer 52, particularly a metal oxide or the like, such as p-type NiO, LaO₃, LaNiO, ZnO, MgZnO, or n-type MoO₃ or WO₃ having a deep conduction band minimum (CBM). The hole injection layer 52 can be formed by sputtering or vapor deposition. However, if the material of the hole injection layer 52 can be made into nanoparticles, the hole injection layer 52 can also be formed by application using an appropriate colloidal solution.

Note that the hole injection layer 52 is not essential and may be omitted in accordance with the desired element structure and characteristics.

### Hole Transport Layer

The hole transport layer 53 is a layer including a material with hole transport properties and having a function of increasing an efficiency of hole transport to the light-emitting layer 54. In a case in which an organic material is used for the hole transport layer 53, preferably an organic material having a HOMO level aligned with that of the light-emitting layer material, including polyvinylcarbazole (PVK), tetrafluoroborate (TFB), poly-TPD, or the like is employed as the organic material. Further, for the hole transport layer 53, a metal residue having a valence band maximum (VBM) aligned with that of the light-emitting layer material, such as NiO, MgNiO, or LaNiO, or a semiconductor material, such as p-type ZnO, may be used. For example, when PVK is used as the material, the hole transport layer 53 may be formed by applying a solution obtained by dissolving PVK in a solvent such as toluene. Further, when an inorganic material is used as the material, the hole transport layer 53 may be formed by sputtering or vapor deposition. In a case in which the hole transport layer 53 includes a material that can be made into nanoparticles, the hole transport layer 53 may be formed by application.

### Light-Emitting Layer

The light-emitting layer 54 includes a quantum dot 100. Details of a structure of the quantum dot 100 will be described below with reference to different drawings. The light-emitting layer 54 further includes a polar ligand 2. The polar ligand 2 will also be described below with reference to different drawings. In the present specification, the term “ligand” includes not only a ligand actually bound to the surface of the quantum dot, but also a ligand which can bind to the surface but is not bound thereto.

### Electron Transport Layer

The electron transport layer 55 is a layer including a material having electron transport properties and having a function of increasing an efficiency of electron transport to the light-emitting layer 54. As a material of the electron transport layer 55, a ZnO-based inorganic material, such as ZnO, IZO, ZAO, or ZnMgO, or TiO₂ can be used. However, the electron transport layer 55 is not limited thereto, and may include an organic material. The electron transport layer 55 is formed by, for example, sputtering or application of a colloidal solution.

### Cathode

The cathode 56 is an electrode member including a material having electrical conductivity. Like the electron transport layer 55, the cathode 56 is formed by vapor-depositing or sputtering a used metal in the related art having a relatively shallow work function, such as Al or Ag.

The light-emitting element 5 according to the present embodiment is a top-emission element, but the structure of the light-emitting element is not limited thereto and may be a bottom-emission type. When the light-emitting element 5 is a bottom-emission element, the anode 51 may be a transmissive electrode and the cathode 56 may be a reflective electrode. The light-emitting element 5 may have a conventional structure or an inverted structure. For example, when the light-emitting element 5 has an inverted structure, the light-emitting element 5 may have a structure in which the layers are layered in the reverse order of the layering order illustrated in FIG. 1.

Each of the layers described above can be replaced as appropriate to constitute the element if a material having better properties is found.

### Plane Index and Direction Index of Mirror

In this specification, Miller indices are used to specify crystal planes. That is, for crystals other than a hexagonal crystal, given unit lattice vectors a₁, a₂, a₃ and integers h, k, l, a crystal plane passing through three points specified by l/h*vector a₁, l/k*vector a₂, and l/l*vector a₃ is referred to as an (hkl) plane. Further, for a hexagonal crystal, given further a unit lattice vector a₄ defined by a₄: =−a₁−a₂ and an integer m defined by l: =−h−k, a crystal plane passing through the three points described above is referred to as an (hkml) plane.

In this specification, for a crystal other than a hexagonal crystal, the (hkl) plane and planes equivalent to the (hkl) plane are collectively referred to as (hkl) equivalent planes. Further, for a hexagonal crystal, the (hkml) plane and planes equivalent to the (hkml) plane are collectively referred to as (hkml) equivalent planes.

In this specification, Miller indices are used to specify crystal directions. That is, for crystals other than a hexagonal crystal, given unit lattice vectors a₁, a₂, a₃ and integers p, q, r, a direction along a composite vector specified by p*vector a₁+q*vector a₂+r*vector a₃ is referred to as a [pqr] direction. Further, for a hexagonal crystal, given further a unit lattice vector a₄ defined by a₄: =−a₁−a₂ and an integer s defined by s: =−p−q, a direction along the composite vector described above is referred to as a [pqsr] direction.

### Structure of Quantum Dot

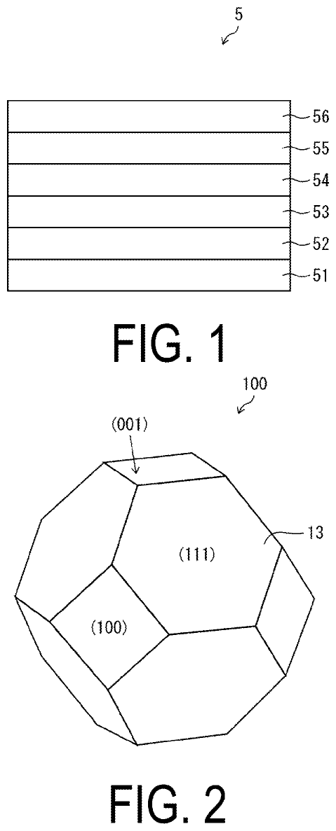

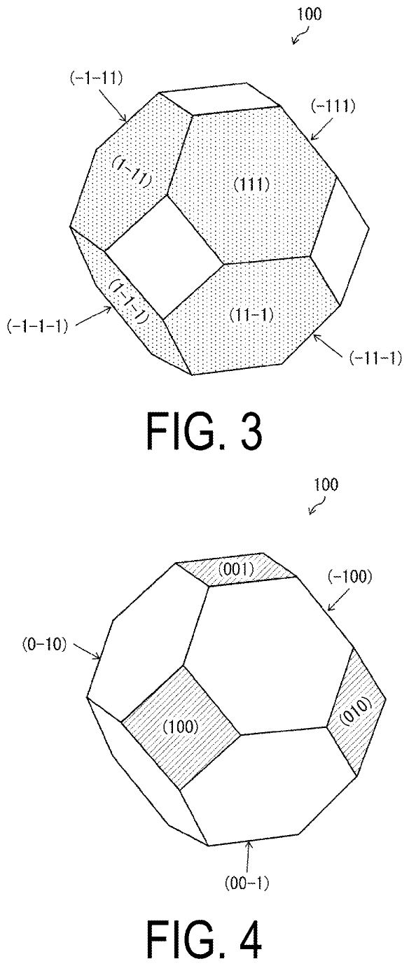

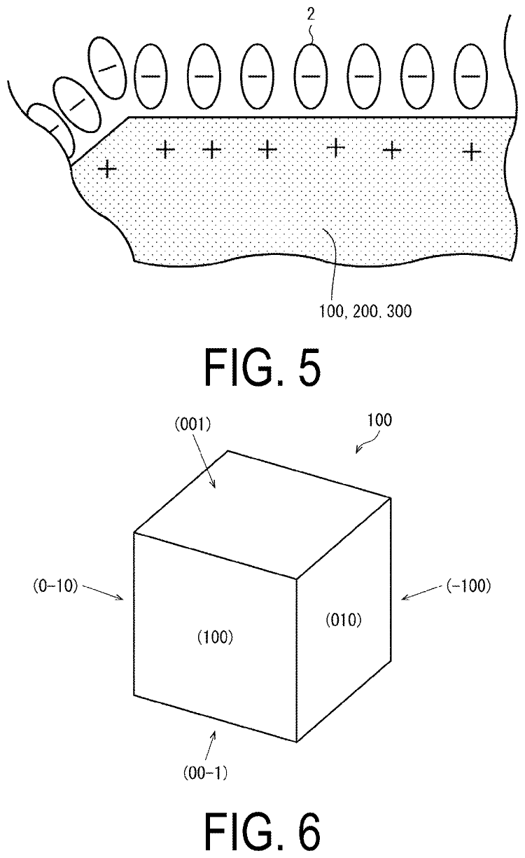

FIG. 2 is a perspective view illustrating a structure of an example of the quantum dot 100 according to this first embodiment. FIG. 3 and FIG. 4 are views illustrating a plane orientation of each crystal plane of the quantum dot 100 illustrated in FIG. 2. FIG. 5 is a schematic view schematically illustrating a surface of the quantum dot 100 illustrated in FIG. 2 and polar ligands protecting the surface.

The quantum dot 100 according to the first embodiment has a zinc-blende crystal system. The quantum dot 100 preferably includes at least one material selected from the group consisting of those that can spontaneously form a zinc-blende crystal system. Examples of the material include a group II-VI compound such as ZnS, CdSe, or ZnSe, and a group III-V compound such as InP. In the disclosure, a group II-VI compound refers to a compound including a group II element and a group VI element, and a group III-V compound refers to a compound including a group III element and a group V element. Further, the group II element may include a group 2 element and a group 12 element, the group III element may include a group 3 element and a group 13 element, the group V element may include a group 5 element and a group 15 element, and the group VI element may include a group 6 element and a group 16 element. Further, groups of elements using Roman numerals are based on the former Chemical Abstracts System (CAS), and groups of elements using Arabic numerals are based on the current nomenclature of the International Union of Pure & Applied Chemistry (IUPAC).

The quantum dot 100 has a core structure, a core-shell structure, or a core-multi-shell structure. In this specification, a “surface of the quantum dot 100” refers to the surface of an outermost layer of the quantum dot 100. In this specification, a “crystal plane of the quantum dot 100” refers to the crystal plane of the outermost layer of the quantum dot 100. In this specification, a “crystal system of the quantum dot 100” refers to the crystal system of the outermost layer of the quantum dot 100.

When the quantum dot 100 has a core-shell structure, the crystal system of the core and the crystal system of the shell may be the same or different from each other. Similarly, when the quantum dot 100 has a core-multi-shell structure, the crystal system of the core and the crystal system of an innermost layer of the multi-shell may be the same or different from each other, and the crystal systems of the layers of the multi-shell adjacent to each other may be the same or different from each other. When a plurality of layers are layered, it is known that, if a certain layer is thin (typically, a three-atom layer or less), the crystal system of the layer usually follows the crystal system of the lower layer underlying that layer. On the other hand, it is known that, if a certain layer is thick, the crystal system of the layer usually follows one of the crystal systems that the material forming the layer can spontaneously achieve in bulk.

When the quantum dot 100 has a core-shell structure, a band gap of the core is preferably smaller than a band gap of the shell to capture and recombine positive holes and electrons in the core. Specifically, preferably an electron affinity of the core is higher than an electron affinity of the shell, and an ionization energy of the core is lower than an ionization energy of the shell.

The quantum dot 100 is a polyhedral crystal including a plurality of crystal planes, and a surface thereof is mainly constituted by polar planes. The surface of the quantum dot 100 includes, for example, 14 planes consisting of (a) a (100) plane, a (−100) plane, a (010) plane, a (0−10) plane, a (001) plane, and a (00−1) plane, each having a quadrangular shape and illustrated in FIG. 4, and (b) a (111) plane, a (−111) plane, a (1−11) plane, a (−1−11) plane, a (11−1) plane, a (−11−1) plane, a (1−1−1) plane, and a (−1−1−1) plane, each having a hexagonal shape and illustrated in FIG. 3. In this case, the ideal shape of the quantum dot 100 is a tetradecahedron obtained by cutting off each vertex of a regular octahedron with a square.

FIG. 3 is a view illustrating planes equivalent to the (111) plane of the crystal planes of the quantum dot 100. In FIG. 3, the (111) plane and the planes equivalent to the (111) plane are shaded. Of the crystal planes of the quantum dot 100, the planes equivalent to the (111) plane are the (−111) plane, the (1−11) plane, the (−1−11) plane, the (11−1) plane, the (−11−1) plane, the (1−1−1) plane, and the (−1−1−1) plane. FIG. 4 is a view illustrating the planes equivalent to the (100) plane of the crystal planes of the quantum dot 100. In FIG. 4, the (100) plane and the planes equivalent to the (100) plane are shaded. Of the crystal planes of the quantum dot 100, the planes equivalent to the (100) plane are the (−100) plane, the (010) plane, the (0−10) plane, the (001) plane, and the (00−1) plane.

The (111) equivalent planes and the (100) equivalent planes in the zinc-blende crystal system are polar planes. A polar plane is a crystal plane in which a valence of cations and a valence of anions exposed on the surface are not balanced. Specifically, a polar plane is a positively charged plane due to the presence of more cations than anions on the surface, and capable of binding strongly to negatively charged polar ligands. In contrast, a non-polar plane is a crystal plane in which the valence of cations and the valence of anions exposed are balanced. Specifically, a non-polar plane is a plane with an electrically neutral surface free of charge and can bind strongly to non-polar ligands.

Note that whether a plane is polar or non-polar can be identified by the method described in “Method for Analyzing Crystal Planes of Quantum Dot” below. When the surface of the quantum dot 100 is constituted by polar planes, the surface of the quantum dot 100 can be protected (surface-protected) by using the polar ligands 2, as illustrated in FIG. 5. The polar ligand 2 can form a coordination bond with a polar plane via an unshared electron pair.

With regard to the relationship between a percentage of polar planes of the quantum dot and a durable time of the light-emitting element, a quantum dot light-emitting element was prepared by using a quantum dot with a surface including polar planes accounting for an area percentage of 50% and forming coordinate bonds with polar ligands only, and the durable time was measured. As a result, a luminance half-life of approximately 6400 hours at a driving luminance of 1000 cd/m² was obtained. When polar planes account for 50% of the planes, the remaining 50% are non-polar planes. At these non-polar planes, bonds with the polar ligands are weak and thus the polar ligands are readily separated from these non-polar planes. The separation of the ligands generates a defect level on the quantum dot surface, and non-radiative recombination of excitons is induced via this defect level. Accordingly, in this case, assuming that the probability of non-radiative recombination is determined by the ratio at which the defect level is present on the surface, the probability of non-radiative recombination can be expressed as 0.5 pₐ (with non-polar planes accounting for 50%). Here, pₐ (0<pₐ<1) is the probability that, in a case in which a quantum dot is used that includes a surface including non-polar planes accounting for an area percentage of 100% and forms coordination bonds with polar ligands only, the polar ligands separate from the non-polar planes, resulting in a defect level and inducing, via this defect level, the non-radiative recombination of excitons.

Note that non-radiative recombination applies thermal energy to the quantum dot and deactivates the quantum dot with a certain probability. Given p_{b} (0<p_{b}<1) as the probability of deactivation of a quantum dot (QD) due to non-radiative recombination, the probability of deactivation of a QD per average time required for one exciton recombination is regarded as 0.5pₐp_{b}.

Given c as a generalized ratio of non-polar planes set to 0.5 in the above, N(t) as a number of quantum dots not deactivated at time t, and f as an average number of exciton recombinations per unit time, the amount of quantum dots deactivated per unit time is:

dN/dt=−pₐp_{b}cfN(t).

With the number N(t) of quantum dots not deactivated and a luminance L(t) of the quantum dot light-emitting element being proportional to each other, given N=kL (where k is any positive real number), the equation can be expressed as:

dL/dt=−pₐp_{b}cfkL(t) (1).

The solution of equation (1), given an initial condition L(0)=L₀, then becomes:

L(t)=L₀·exp(−pₐp_{b}cfkt) (2).

From equation (2), the luminance half-life t_{1/2} is:

t_{1/2}=In(2)/pₐp_{b}cfk (3).

When the test values in equation (3), c=0.5 and t_{1/2=6400} hours, are substituted, then pₐp_{b}fk≈2.17×10\hat{ }−4 and equation (3) becomes:

T_{1/2}=3200/λ (4).

Here, when the percentages of polar planes are 70%, 80%, and 90%, the ratios c of non-polar planes are 0.3, 0.2, and 0.1, respectively. Then, when these are substituted into (4), the luminance half-lives t_{1/2} are 10667 hours, 16000 hours, and 32000 hours, respectively. Assuming that the light-emitting element including the quantum dot of the present application is used for a television display and the television viewing time per day is three hours, these values are then 9.74 years, 14.6 years, and 29.2 years.

As described above, the durable time of the light-emitting element was estimated for a configuration in which the quantum dot light-emitting layer 54 includes only the polar ligands 2 as the ligands for protecting the surface of the quantum dot 100. The light-emitting element 5 that uses the quantum dot 100 having a percentage of polar planes occupying the surface of the quantum dot 100 (hereinafter, referred to as “area percentage of polar planes”) of 70% is expected to have a luminance half-life of 10000 hours or more at 1000 cd/m². A luminance half-life of 10000 hours or more at 1000 cd/m² corresponds to approximately 10 years in terms of a display service life. A service life of 10 years is generally a sufficient durable lifetime for commercialization. Further, for the light-emitting element 5 of blue light emission that uses the quantum dot 100 having an area percentage of polar planes of 80% or more, a result corresponding to approximately 15 years in terms of a display service life is expected. Further, for the light-emitting element 5 of blue light emission that uses the quantum dot 100 having an area percentage of polar planes of 90% or more, a result corresponding to approximately 30 years in terms of a display service life is expected.

Accordingly, when 70% or more of the surface of the quantum dot 100 is constituted by polar planes, the surface of the quantum dot 100 can be sufficiently protected (surface-protected) by using the polar ligands 2 alone.

As the area percentage of polar planes occupying the surface of the quantum dot 100 increases, the effect of surface protection by the polar ligands 2 improves. Therefore, the surface of the quantum dot 100 according to the first embodiment need only include polar planes accounting for an area percentage of 70% or more, preferably 80% or more, and more preferably 90% or more. Further, ideally the surface of the quantum dot 100 includes polar planes only.

Here, the effect of protecting the surface of the quantum dot by the polar ligands or the neutral ligands is evaluated by evaluating a binding energy of the polar ligands at the polar planes and the non-polar planes of the surface of the quantum dot. Specifically, in a case in which the surface of the quantum dot 100 is made of CdSe and the polar ligands 2 are carboxylic acid-based ligands, the binding energy per mol of the polar ligands 2 to the surface of the quantum dot 100 was calculated. This calculation was performed on the basis of the density functional theory (DFT). The calculation result showed that the binding energy to the (100) equivalent plane and to the (111) equivalent plane, which are polar planes, is about 240 kcal/mol, while the binding energy to the (110) equivalent plane, which is a non-polar plane, is about 16 kcal/mol.

The binding energies thus differ by one digit or more. As a result, in a case in which the surface of a known quantum dot without a controlled percentage of polar planes is protected by the polar ligands 2 only, deterioration of the known quantum dot progresses from the non-polar planes. Further, in a case in which the surface of the known quantum dot is protected by the neutral ligands 3 only, deterioration of the known quantum dot progresses from the polar planes. As a result, in known techniques such as those in PTLs 1 and 2, to protect the surface of the known quantum dot by using both polar ligands and neutral ligands, a process of mixing the polar ligands and the neutral ligands or a process of ligand exchange is required.

On the other hand, in the quantum dot 100 according to the first embodiment, the area percentage of polar planes is 70% or more. Accordingly, the area percentage of non-polar planes in the quantum dot 100 is small. Further, the polar ligands 2 bonded to the polar planes of the quantum dot 100 inhibit the approach of another quantum dot 100 to the non-polar planes of the quantum dot 100. As a result, even when the surface of the quantum dot 100 is protected only by the polar ligands 2, the non-polar planes of the quantum dot 100 are unlikely to deteriorate. Therefore, the manufacturing method of the light-emitting layer 54 according to the first embodiment does not require a process of mixing the polar ligand and the neutral ligand or a process of performing ligand exchange. Accordingly, the light-emitting layer 54 according to the first embodiment has high manufacturing efficiency. Further, the ligands used to protect the surface of the quantum dot 100 may be a single type.

The polar ligand 2 may be organic, and includes, for example, at least one type selected from the group consisting of organic polar ligands including any one or more of a thiol group, an alkoxyl group, a carboxyl group, a phosphonic acid group, and a phosphinic acid group at a terminal. The ligand including one or more thiol groups at a terminal partially includes a structure represented by the following structural formula (1) or the following structural formula (2) in an ionized state. The ligand including an alkoxyl group at a terminal partially includes a structure represented by the following structural formula (3) in an ionized state. The ligand including a carboxyl group at a terminal partially includes a structure represented by the following structural formula (4) in an ionized state. The ligand including a phosphonic acid group at a terminal partially includes a structure represented by the following structural formula (5) or the following structural formula (6) in an ionized state. The ligand including a phosphinic acid group at a terminal partially includes a structure represented by the following structural formula (7) in an ionized state.

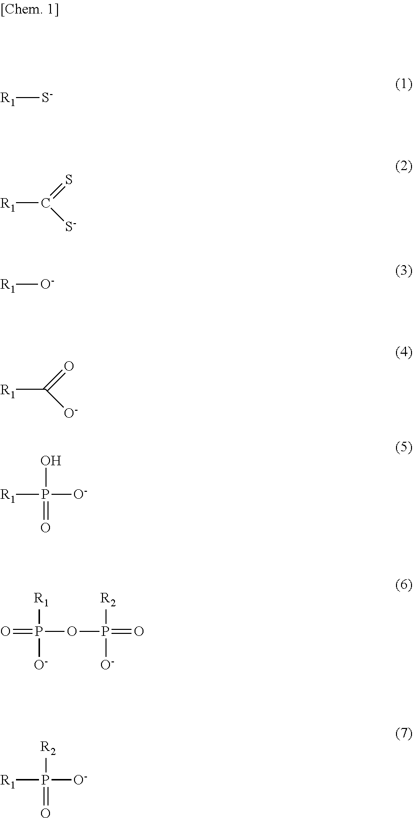

Note that, in the structural formulae (1) to (7), C represents a carbon atom, O represents an oxygen atom, O⁻ represents an oxide ion, S represents a sulfur atom, S⁻ represents a sulfide ion, P represents a phosphorus atom, and R₁ and R₂ each independently represent a hydrogen atom, an alkyl group, an aryl group, an alkoxyl group, or an unsaturated hydrocarbon group.

The polar ligand 2 is preferably organic. Unlike inorganic ligands, organic ligands can have a chain-like long molecular structure. Therefore, the organic ligand readily maintains a long distance between the quantum dots 100, making it possible to improve a dispersibility and a storability of the quantum dots 100 in a solution.

The polar ligand 2 may be inorganic, and includes at least one type selected from the group consisting of inorganic polar ligands represented by the ionic formulae Cl⁻, Br⁻, I⁻, SCN⁻, CN⁻, OH⁻, SH⁻, SeH⁻, TeH⁻, Se²⁻, S²⁻, Te²⁻, Sn₂S₆⁴⁻, Sn₂Se₆⁴⁻, In₂Se₄²⁻, In₂Te₄²⁻, Ga₂Se₄²⁻, Sb₂Se₄²⁻, and Sb₂Te₄²⁻, in an ionized state, for example.

The polar ligand 2 is also preferably inorganic. Organic bonds (such as C—H and C—C) are readily broken by heat and light. In a case in which the polar ligand 2 is inorganic, the polar ligand 2 does not include an organic bond and thus is less likely to decompose, thereby making it possible to improve the reliability of the light-emitting layer 54 and the light-emitting element 5. The polar ligand 2 is more preferably any one of Se²⁻, S²⁻, and Te²⁻. This is because Se²⁻, S²⁻, and Te²⁻ do not include chemical bonds and thus do not decompose and, being negative divalent, can bond strongly to the polar planes of the quantum dot 100.

When a film is formed by application by using a colloidal solution in which the quantum dots 100 are dispersed, to obtain a uniform thickness and decrease surface unevenness, it is necessary that (1) the quantum dots 100 do not aggregate in the solution and (2) the flow of the solvent is not inhibited. To satisfy (1), the ligands coordinated to the surface of the quantum dot 100 need only have a high density with respect to the volume of the quantum dots 100 in the applied colloidal solution. To satisfy (2), an inertia of the quantum dots 100 in the applied colloidal solution need only be low with respect to a viscosity of the solvent of the colloidal solution. Here, as the size of the quantum dot 100 in the colloidal solution decreases, both (1) and (2) are more likely to be satisfied. Therefore, in consideration of the size that does not affect a fluidity of the colloidal solution, the size of the quantum dot 100 is preferably 10 nm or less. In other words, as long as the size is 10 nm or less, when the light-emitting layer 54 (refer to FIG. 1) of the light-emitting element is formed by application or the like, a uniform film can be formed.

Here, the size of the quantum dot 100 may be a nominal value or a design value, or may be a measured value. In the case of a measured value, the size of the quantum dot 100 is, for example, a value obtained by measuring a particle diameter of the quantum dot 100 a plurality of times by using transmission electron microscopy (TEM) or the like and averaging the measured values.

### Manufacturing Method of Quantum Dot

Examples of the method for manufacturing the quantum dot 100 include a heating method, hot injection, a microwave-assisted method, and a continuous flow method. These manufacturing methods will now be described.

### Heating Method

The heating method is a technique of synthesizing each layer of the quantum dot 100 by mixing a material in an organic solvent and heating the mixture to thermally decompose and react the material. In the heating method, an organometallic compound is used. The compound is obtained by using trioctylphosphine (TOP) or trioctylphosphine oxide (TOPO) as the organic solvent and bonding dimethylcadmium as a group II raw material with desired elements such as, for example, a TOP complex of S, Se and Te, or a methyl group or an ethyl group, as a group VI raw material. Each layer of the quantum dot 100 can be synthesized by mixing the group II and group VI raw materials in the organic solvent, heating the mixture to about 300° C. to thermally decompose the raw materials, and maintaining a high degree of supersaturation of the group II and group VI elements in the organic solvent to promote a reaction of the group II-VI compound.

### Hot Injection

Hot injection is a technique of rapidly injecting raw materials into a heated organic solvent, thereby utilizing supersaturation in the vicinity of the injection region to generate uniform crystal growth nuclei at a high density. In hot injection, as the raw materials, TOP or T-TOPO is used as the organic solvent and is heated to about 300° C., and group II and group VI raw materials are rapidly injected into the organic solvent to rapidly increase local supersaturation around the injection region and generate uniform crystal growth nuclei at a high density. With the high degree of supersaturation localized in the vicinity of the injection region, the raw materials consumed by the growth of the growth nuclei are supplied at any time by diffusion from the surrounding region having a low degree of supersaturation due to the concentration gradient, and the growth of the quantum dots continues. In this technique, alkylphosphine and trioctylphosphine or an alkylphosphine oxide such as trioctylphosphine oxide, a long-chain carboxylic acid such as oleic acid, and a long-chain amine such as oleamine are added as surfactants or ligands that prevent quantum dot aggregation due to the high density of nucleation.

### Microwave-Assisted Method

The microwave-assisted method is a technique of selectively heating growth raw materials by utilizing microwaves. In this technique, because heating is selective, a controllability of the reaction is favorable, making it possible to increase the temperature in a short period of time to a range required for reaction. Further, compared with the injection method, the quantum dots can be readily synthesized, even in the atmosphere. Microwaves are selectively resonantly absorbed by molecules having polarization and therefore, when a chalcogenide suitable for the wavelength of the microwaves is used as a raw material, for example, the raw material can be selectively heated, making it possible to control the growth of quantum dots. Because of this feature, the raw materials must have polarization and raw materials different from those in the first and second techniques described above are used. Examples of the raw materials include a mixed solution of cadmium stearate, an alkane solvent, and a group VI powder.

### Continuous Flow Method

The continuous flow method is a technique of causing a nucleation reaction and a growth reaction to occur in different reactors by conducting a reaction of raw materials while producing a flow of an organic solvent mixed with the raw materials. With the nucleation reaction and the growth reaction occurring in different reactors, an appropriate temperature gradient can be precisely set, and each reaction can be precisely controlled. This technique is suitable for mass production, offering relatively easy control of crystal growth. In the continuous flow method as well, the quantum dots 100 can be grown either in an organic solution or in a gas phase including vapor of an organic solution as described in the three manufacturing methods above. In the continuous flow method, the nucleation and growth reaction can be precisely controlled in separate reactors by mixing an organic solvent with group II and group VI raw materials, moving the raw materials following the flow of the liquid phase or the gas phase, and setting a temperature gradient suitable for the nucleation stage, which is the starting point of growth of the quantum dots 100, and the crystal growth stage. Conditions suitable for each stage can be precisely and independently controlled by separating nucleation and crystal growth into individual vessels and carrying out transport in a liquid or vapor stream between the vessels.

In crystal growth, it is important to maintain a high degree of supersaturation in the raw materials, which is a driving force for nucleation and crystal growth, and the four types of manufacturing methods described above, for example, have been developed because of differences in means for realizing and maintaining such a condition.

To synthesize the quantum dot 100, it is necessary to control synthesis conditions when synthesizing each layer of the quantum dot 100. Specifically, it is necessary to control the synthesis conditions of each layer of the quantum dot 100, ensuring that the surface of the quantum dot 100 has a shape terminating at the (111) equivalent planes and the (100) equivalent planes only, as illustrated in FIG. 2. Examples of methods for selectively causing specific crystal planes to appear as described above include, in the process of synthesizing each layer, controlling, within a specific range, the pH of the solvent in which the materials are mixed. Experiments revealed that, to obtain the crystal planes illustrated in FIG. 2, the pH of the solvent need only be maintained within a range from 9 to 11. The pH in this range is weakly basic with an H+ concentration higher than that of a neutral condition of pH=7, suggesting that an intermediate reaction between H+ and the raw materials is involved in the mechanism of preferentially forming specific crystal planes.

As another method, in a case in which group II-VI crystals such as ZnS or CdS or group III-V crystals such as InP are used, for example, it has been found that (111) equivalent planes appear by relatively decreasing the group VI or group V raw materials. This is because, as the group V or group VI raw materials are decreased, the number of non-bonding orbitals on the (111) equivalent planes, which have a high surface density of bonding orbitals, relatively increases.

When the conditions for forming the outermost layer (and the layer immediately below the outermost layer when the outermost layer is thin) of the quantum dot 100 are any of the conditions described above, the quantum dot 100 including 14 planes of (111) equivalent planes and (100) equivalent planes is obtained. Here, after the temperature is lowered to stop the reaction, heat may be applied for heat treatment. In general, defects on the surface of the outermost layer of the quantum dot 100 can be reduced by stopping the reaction and performing heat treatment.

To coordinate the polar ligands 2 to the quantum dot 100 manufactured as described above, the polar ligands 2 are added in a sufficient amount after preparation of the quantum dot 100, and the mixture is then heated at 150° C. for 20 minutes for ligand replacement. Additionally, the polar ligands 2 can be added at the final stage of crystal growth of the quantum dot 100 or at the time of shell formation to obtain the quantum dot 100 including polar planes coordinated with the polar ligands 2.

Note that a particle size of the quantum dot 100 may be from 3 nm to 40 nm, not including the polar ligands 2.

### Method for Analyzing Crystal Planes of Quantum Dot

Next, a method for analyzing the crystal planes of the quantum dot 100 will be described. Simply, the crystal planes of the quantum dot 100 can be analyzed by observing the quantum dot 100 with a known X-ray diffraction (XRD) measurement device, energy dispersive X-ray spectroscopy (EDS) measurement device, X-ray photoelectron spectroscopy (XPS) measurement device, transmission electron microscopy (TEM) device, or the like.

The crystal system of the quantum dot 100 can be measured by X-ray diffraction. If the quantum dot 100 is as thick as about 20 nm, a typical powder X-ray diffraction method can be used to detect a diffraction peak from each crystal plane with sufficient accuracy. Therefore, the crystal system of the quantum dot 100 can be measured by checking the obtained spectral shape against a database or previous literature values.

Further, the composition of the quantum dot 100 can be analyzed by EDS or XPS. This is because, depending on the composition of the quantum dot 100, a peak specific to an element included in the composition or a bonding state thereof appears in the spectroscopic result.

The crystal plane spacing and the crystal plane indices of the quantum dot 100 can be calculated on the basis of the composition and the crystal system of the quantum dot 100. These values can then be combined with TEM observations to determine the plane indices and ratio of the nanoparticle surface. Lastly, the area percentage of polar planes occupying the surface of the quantum dot 100 can be calculated on the basis of the composition, the crystal system, and the crystal plane indices.

Typically, the light-emitting layer 54 has a uniform configuration regardless of location in terms of the shape and the plane indices of the quantum dot 100, the type and percentage of the ligands, and the like. Therefore, the result of an analysis performed on a portion of the light-emitting layer 54 may be applied to the entire light-emitting layer 54.

Further, when the thinness of the outermost layer of the quantum dot 100 makes analysis difficult (typically, a three-atom layer or less), the portion to be analyzed by the analysis method described above includes the lower layer underlying the outermost layer. As described above, if the outermost layer is thin, the crystal system of the outermost layer follows the crystal system of the lower layer. Therefore, regardless of the thickness of the outermost layer of the quantum dot 100, the crystal system and the crystal indices derived on the basis of the analysis method described above may be regarded as the crystal system and the crystal indices of the outermost layer of the quantum dot 100.

Typically, even when the quantum dot 100 having an area percentage of polar planes of 100% is analyzed, the calculated area percentage of polar planes tends to be 90% or more and less than 100% due to analysis accuracy, measurement limits, impurities, and the like. Therefore, if the calculated area percentage of polar planes is 90% or more, the probability that the light-emitting layer 54 includes quantum dots with polar planes accounting for 100% of the surface is regarded as high. Accordingly, if the area percentage of polar planes in the analysis result is 90% or more, the light-emitting layer 54 is regarded as including quantum dots with polar planes accounting for 100% of the surface.

Further, as described above, the polar planes need only account for 70% or more of the surface of the quantum dot 100. In a case in which the quantum dot 100 having an area percentage of polar planes of 70% is used, the calculated area percentage of polar planes tends to be from 60% to 80%. Therefore, in a case in which the calculated area percentage of polar planes is 60%, the probability that the quantum dots 100 having an area percentage of polar planes of 70% or more are included throughout the light-emitting layer 54 is regarded as high. As described above, in a case in which 70% or more of the surface of the quantum dot 100 are polar planes, the surface of the quantum dot 100 can be sufficiently protected (surface-protected) by using the polar ligands 2 only. Accordingly, when the area percentage of polar planes in the analysis result is 60% or more, at least some of the quantum dots 100 included in the light-emitting layer 54 are sufficiently surface-protected by the polar ligands 2 alone.

Further, the area percentage of non-polar planes can also be determined by the same method as described above. If the calculated area percentage of non-polar planes is 90% or more, the light-emitting layer 54 is regarded as including the quantum dot 100 with non-polar planes accounting for 100% of the surface.

### Ligand Analysis Method

The functional groups of the ligands, including the polar ligands 2 and neutral ligands 3 described below, can be determined by using a mass spectrometer. When the ligand is organic, the ligand is ionized and cut into a plurality of fragments, and the mass/charge (m/z) value of each fragment and an intensity ratio in the mass spectrum are acquired. Then, on the basis of the m/z value and the intensity ratio, the structural formula and the functional group of the ligand can be determined with reference to a database.

Most organic compounds are registered in a database, making identification possible by reference to the database. Even if, in the unlikely event, the ligand is an unregistered organic compound, the ligand can be searched by analogy with the registered organic compounds.

Further, when the ligand is inorganic, the compositional formula of the ligand can be determined by using a mass spectrometer or an EDS measurement device. Furthermore, as described above, the result of an analysis performed on a portion of the light-emitting layer 54 may be applied to the entire light-emitting layer 54.

The light-emitting layer 54 is analyzed as described above to identify compounds that may function as ligands included in light-emitting layer 54. Even when only the polar ligands 2 (or only the neutral ligands 3) are used as the ligands in the light-emitting layer 54 at the time of manufacture, the polar ligands 2 (or the neutral ligands 3) tend to be less than 100% of the identified compounds due to analysis accuracy, measurement limits, and the like. Therefore, if, as a substance quantity percentage, the percentage of the polar ligands 2 (or the neutral ligands 3) occupying the identified compounds is 90% or more, the probability that 100% of the ligands included in the light-emitting layer 54 are the polar ligands 2 (or the neutral ligands 3) is regarded as high.

### Modified Example

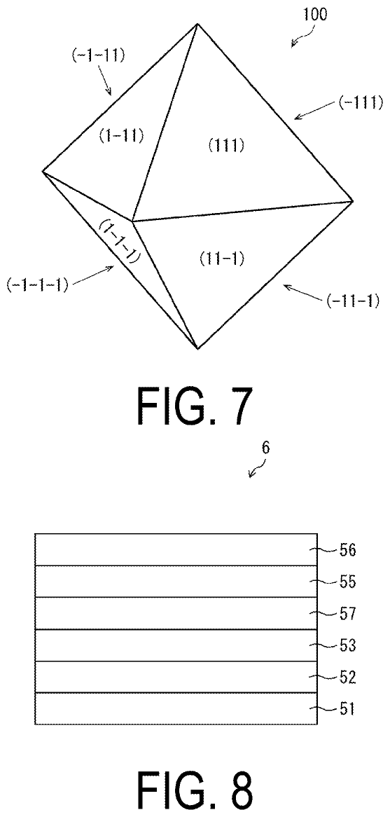

FIG. 6 and FIG. 7 are each a perspective view illustrating a structure of a modified example of the quantum dot 100 according to the first embodiment. FIG. 8 is a cross-sectional view schematically illustrating a solar cell 6 including a photoelectric conversion layer 57 including the quantum dot 100 according to the first embodiment.

The quantum dot 100 according to the first embodiment is not limited to that described above. The surface of the quantum dot 100 may include, for example, six (100) equivalent planes as illustrated in FIG. 6 and, in this case, the ideal shape of the quantum dot 100 is a cuboid. Alternatively, the surface of the quantum dot 100 may include, for example, eight (111) equivalent planes as illustrated in FIG. 7 and, in this case, the ideal shape of the quantum dot 100 is a regular octahedron.

The quantum dot 100 having a hexahedral shape such as illustrated in FIG. 6 can be manufactured by increasing the reaction temperature. For example, when the quantum dot 100 is made of CdSe, the crystals are grown at 275° C. or higher. High temperatures increase the rate of ligand desorption and re-adsorption at the crystal surface, resulting in preferential deposition of atoms on crystal planes having with high surface energies. That is, atoms are preferentially deposited on the (111) equivalent planes having a higher density of dangling bonds. As a result, the surface of the quantum dot 100 is constituted by the (100) equivalent planes.

However, as described above, when a film is formed by application by using a colloidal solution in which the quantum dots 100 are dispersed, to obtain a uniform thickness and decrease surface unevenness, it is necessary that (1) the quantum dots 100 do not aggregate in the solution and (2) the flow of the solvent is not inhibited. To satisfy (2), preferably the quantum dot 100 has a shape that readily rolls, that is, a shape close to a spherical shape. Furthermore, to reduce the drive voltage of the light-emitting element 5, it is necessary that the spacing between the quantum dots 100 in the light-emitting layer 54 is small. Therefore, preferably the quantum dot 100 has a shape that readily fills an area leaving minimal gaps, that is, a shape close to a spherical shape. Accordingly, the shape of the quantum dot 100 is preferably an octahedron rather than a hexahedron, and preferably a tetradecahedron rather than an octahedron.

As illustrated in FIG. 8, the first embodiment can be applied to the solar cell 6. The solar cell 6 includes the anode 51, the hole injection layer 52, the hole transport layer 53, the photoelectric conversion layer 57 (quantum dot layer), the electron transport layer 55, and the cathode 56. The photoelectric conversion layer 57 includes the quantum dot 100 according to the first embodiment and the polar ligand 2.

### Second Embodiment

Another embodiment of the disclosure will be described below. Note that, for convenience of description, members having the same functions as those of the members described in the above-described embodiment will be denoted by the same reference numerals and signs, and the description thereof will not be repeated.

The light-emitting element 5 (refer to FIG. 1) according to the second embodiment differs from the light-emitting element 5 according to the first embodiment described above only in that the light-emitting layer 54 includes a quantum dot 200 according to the second embodiment instead of the quantum dot 100 according to the first embodiment described above.

### Structure of Quantum Dot

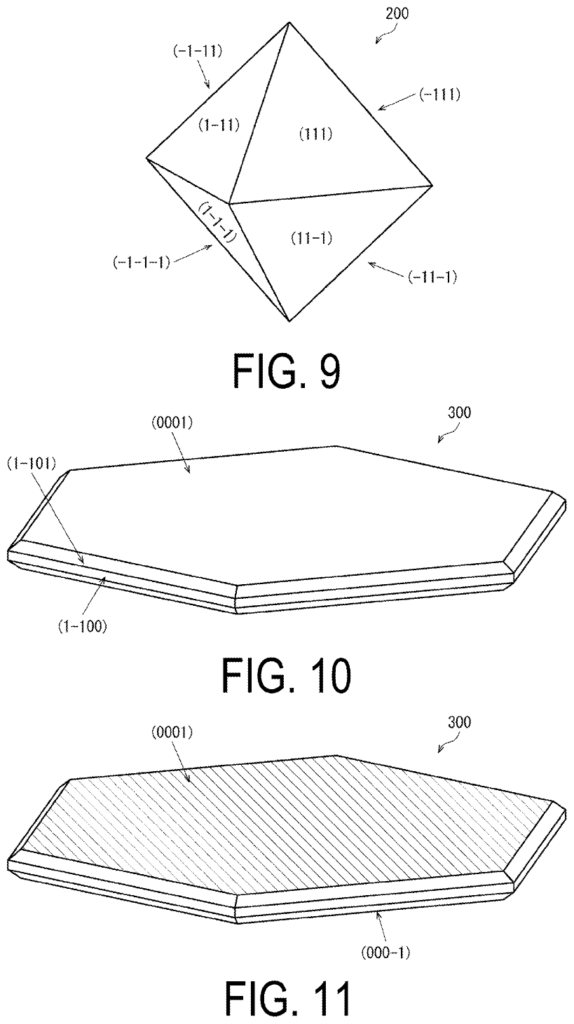

FIG. 9 is a perspective view illustrating a structure of an example of the quantum dot 200 according to this second embodiment.

The quantum dot 200 according to the second embodiment has a sodium chloride crystal system. The quantum dot 200 preferably includes at least one material selected from the group consisting of those that can spontaneously form a sodium chloride crystal system. The material is, for example, a group IV-VI compound such as PbTe, PbSe, or PbS. In this disclosure, a group IV-VI compound means a compound containing a group IV element and a group VI element. The group IV element may include a group 4 element and a group 14 element.

In a case in which the quantum dot 200 according to the second embodiment has a core-shell structure, a band gap of the core is preferably smaller than a band gap of the shell, as in the first embodiment described above.

The quantum dot 200 is a polyhedral crystal including a plurality of crystal planes, and a surface thereof is mainly constituted by polar planes. The surface of the quantum dot 200 includes, for example, eight planes consisting of a (111) plane, a (−111) plane, a (1−11) plane, a (−1−11) plane, a (11−1) plane, a (−11−1) plane, a (1−1−1) plane, and a (−1−1−1) plane, each having a triangular shape, as illustrated in FIG. 9. These eight planes are (111) equivalent planes. In this case, the ideal shape of the quantum dot 200 is a regular octahedron.

The (111) equivalent planes of a sodium chloride crystal are polar planes. The surface of the quantum dot 200 according to the second embodiment, as in the first embodiment described above, need only include polar planes accounting for an area percentage of 70% or more, preferably 80% or more, and more preferably 90% or more. Further, ideally the surface of the quantum dot 200 includes polar planes only.

As in the first embodiment described above, if the calculated area percentage of the polar planes in the crystal plane analysis result of the quantum dot 200 is 90% or more, the light-emitting layer 54 is regarded as including the quantum dot 200 with polar planes accounting for 100% of the surface.

### Manufacturing Method of Quantum Dot

The quantum dot 200 according to the second embodiment may be manufactured by, for example, a heating method, a hot injection method, a microwave-assisted method, or a continuous flow method, as in the first embodiment.

In addition to the manufacturing method described in NPL 1, the quantum dot 100 having an octahedral shape such as illustrated in FIG. 7 can be manufactured by using polar ligands (for example, ligands including a thiol group) that preferentially bond to polar planes during synthesis and lowering the reaction temperature. For example, when the quantum dot 100 is made of PbS, crystals are grown at about 110° C.

The second embodiment can also be applied to a solar cell as in the first embodiment described above.

### Third Embodiment

Another embodiment of the disclosure will be described below. Note that, for convenience of description, members having the same functions as those of the members described in the above-described embodiment will be denoted by the same reference numerals and signs, and the description thereof will not be repeated.

The light-emitting element 5 (refer to FIG. 1) according to a third embodiment differs from the light-emitting element 5 according to the first embodiment described above only in that the light-emitting layer 54 includes a quantum dot 300 according to the third embodiment instead of the quantum dot 100 according to the first embodiment described above.

### Structure of Quantum Dot

FIG. 10 is a perspective view illustrating a structure of an example of the quantum dot 300 according to this third embodiment. FIG. 11 is a view illustrating a plane orientation of each crystal plane of the quantum dot 300 illustrated in FIG. 10.

The quantum dot 300 according to the third embodiment has a wurtzite crystal system. The quantum dot 300 preferably includes at least one material selected from the group consisting of those that can spontaneously form a wurtzite crystal system. The material is, for example, a group II-VI compound such as ZnS, CdSe, or ZnSe. Note that the group II-VI compound may have a zinc-blende crystal system, depending on crystal growth conditions.

In a case in which the quantum dot 300 according to the third embodiment has a core-shell structure, a band gap of the core is preferably smaller than a band gap of the shell, as in the first embodiment described above.

The quantum dot 300 is a polyhedral crystal including a plurality of crystal planes, and a surface thereof is mainly constituted by polar planes. The quantum dot 300 has, for example, a flat plate shape thin in a [0001] direction and includes, as an upper face and a bottom face, two planes consisting of a (0001) plane and a (000−1) plane, each having the hexagonal shape, as illustrated in FIG. 11.

FIG. 11 is a view illustrating a plane equivalent to (0001) of the crystal planes of the quantum dot 300. In FIG. 11, the (0001) plane and the plane equivalent to the (0001) plane are shaded. Of the crystal planes of the quantum dot 300, the plane equivalent to the (0001) plane is the (0001-1) plane opposite to the (0001) plane.

The (0001) equivalent planes and (1−101) equivalent planes in the wurtzite crystal are polar planes. In the quantum dot 300, the (1−101) equivalent planes are the twelve planes consisting of a (1−101) plane, a (01−11) plane, a (−1011) plane, a (−1101) plane, a (0−111) plane, a (10−11) plane, a (1−10−1) plane, a (01−1−1) plane, a (−101−1) plane, a (−110−1) plane, a (0−11−1) plane, and a (10−1−1) plane. The surface of the quantum dot 300 according to the third embodiment, as in the first embodiment described above, need only include polar planes accounting for an area percentage of 70% or more, preferably 80% or more, and more preferably 90% or more. Further, ideally the quantum dot 300 has a flat plate shape.

As in the first embodiment described above, if the calculated area percentage of the polar planes in the crystal plane analysis result of the quantum dot 300 is 90% or more, the light-emitting layer 54 is regarded as including the quantum dot 300 with polar planes accounting for 100% of the surface.

Planes between the upper face and the bottom face of the quantum dot 300 may include a non-polar plane, and may include, for example, a (1−100) equivalent plane. In the quantum dot 300, the (1−100) equivalent planes are the six planes consisting of a (1−100) plane, a (01−10) plane, a (−1010) plane, a (−1100) plane, a (0−110) plane, and a (10−10) plane. The planes between the upper face and the bottom face of the quantum dot 300 preferably includes a polar plane, and preferably include, for example, a (1−101) equivalent plane inclined relative to the (0001) equivalent plane. The planes between the upper face and the bottom face of the quantum dot 300 may include both or one of a non-polar plane and a polar plane.

As illustrated in FIG. 10, because the percentage of the area of the (0001) equivalent planes to the surface of the quantum dot 300 is large, the quantum dot 300 has a flat plate shape thin in the [0001] direction. Therefore, the direction of recombination of the excitons in the quantum dot 300 is mainly a direction substantially perpendicular to the [0001] direction. As a result, light emitted by recombination of the excitons is strongly emitted in a direction substantially parallel to the [0001] direction. At the time of formation of the light-emitting layer 54, the quantum dot 300 is likely to be deposited such that any one of the (0001) equivalent planes of the quantum dot 300 is positioned on an upper face side or a bottom face side of the light-emitting layer 54 due to its own weight. As a result, in the light-emitting element 5, the light-emitting layer 54 emits light mainly in a direction substantially orthogonal to the upper face and the bottom face of the light-emitting layer 54. The incident angle is therefore small, making reflection of the emitted light by a boundary surface of the light-emitting element 5 unlikely, and thus reducing the attenuation of the light inside the light-emitting element 5. In this way, the efficiency at which light is extracted from the light-emitting element 5 is improved.

### Manufacturing Method of Quantum Dot

The quantum dot 300 according to the third embodiment may be manufactured by, for example, a heating method, a hot injection method, a microwave-assisted method, or a continuous flow method, as in the first embodiment described above.

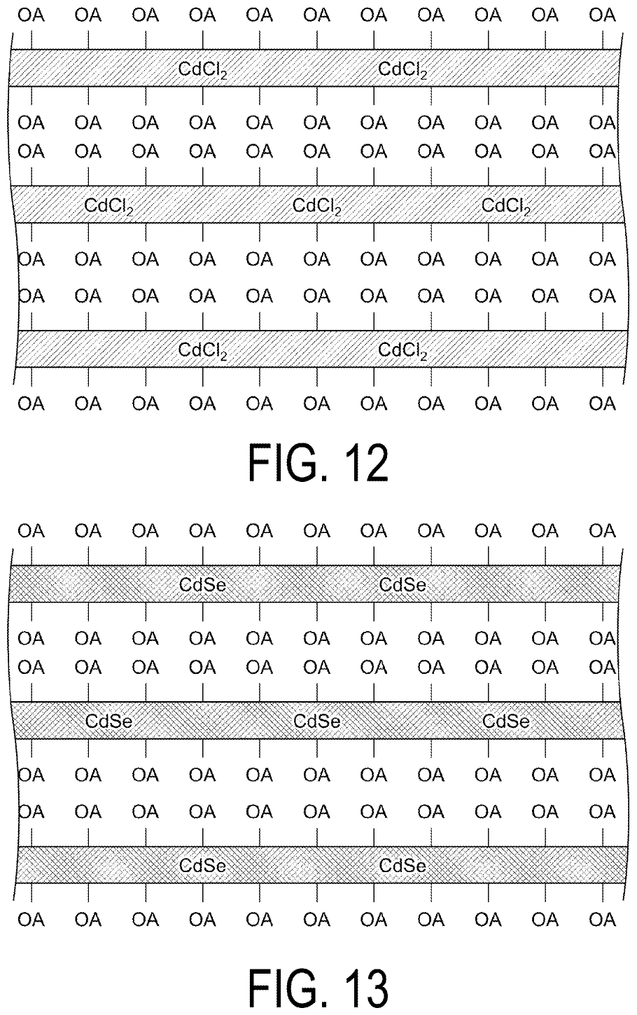

FIG. 12 and FIG. 13 are each a view illustrating the manufacturing method of the example of the quantum dot 300 illustrated in FIG. 10.

The quantum dot 300 having a flat plate shape and a wurtzite structure such as illustrated in FIG. 10 can be manufactured by forming a material having a wurtzite crystal system into a sheet shape and replacing ions, as necessary. For example, when the quantum dot 300 is made of CdSe, first, oleylamine (indicated by OA in FIG. 12) is added to CdCl₂ to form a complex of CdCl₂ having a nano-sheet shape. CdCl₂ is a material that typically has a wurtzite crystal system.

Subsequently, an octylamine solution in which Se is melted is mixed and, at 100° C. for 24 hours, caused to react with the CdCl₂ complex described above. As a result, as illustrated in FIG. 13, two chloride ions Cl⁻ are replaced by one selenide ion Se⁻ to form a CdSe complex having a nano-sheet shape. The CdSe thus formed has a flat plate shape and a wurtzite crystal system.

### Modified Example

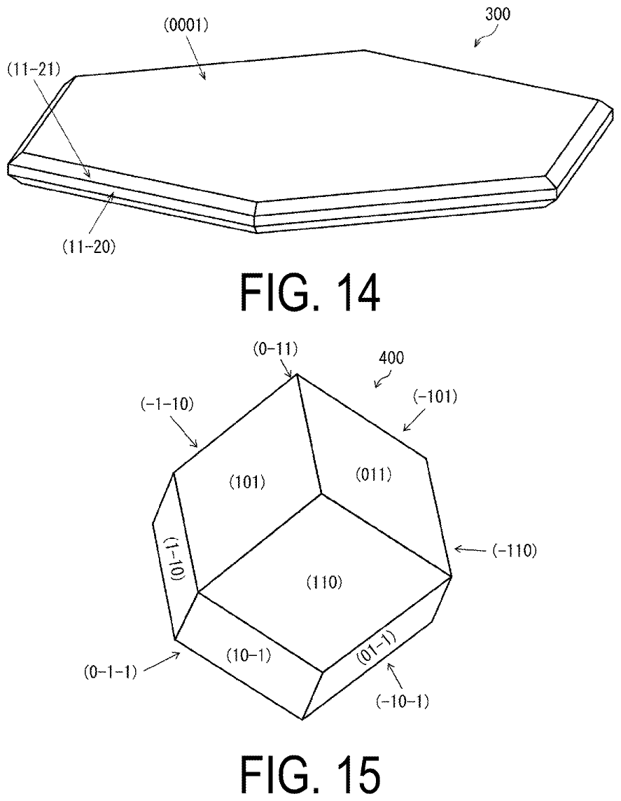

FIG. 14 is a perspective view illustrating a structure of a modified example of the quantum dot 300 according to this third embodiment.

The planes between the upper face and the bottom face of the quantum dot 300 may include, for example, a (11−20) plane and planes equivalent to the (11−20) plane, as illustrated in FIG. 14, as non-polar planes. The planes between the upper face and the bottom face of the quantum dot 300 may include, for example, a (11−21) plane and planes equivalent to the (11−21) plane as polar planes. The planes equivalent to (11−20) are a (−2110) plane, a (1−210) plane, a (−1−120) plane, a (2−1−10) plane, and a (−12−10) plane. The planes equivalent to (11−21) are a (−2111) plane, a (1−211) plane, a (−1−121) plane, a (2−1−11) plane, a (−12−11) plane, a (−2111) plane, a (11−2−1) plane, a (1−21−1) plane, a (−1−12−1) plane, a (2−1−1−1) plane, and a (−12−1−1) plane.

Hereinafter, the (11−20) plane and the planes equivalent to the (11−20) plane are collectively referred to as (11−20) equivalent planes, and the (11−21) plane and planes equivalent to the (11−21) plane are collectively referred to as (11−21) equivalent planes.

The third embodiment can also be applied to a solar cell as in the first embodiment described above.

### Fourth Embodiment

Another embodiment of the disclosure will be described below. Note that, for convenience of description, members having the same functions as those of the members described in the above-described embodiment will be denoted by the same reference numerals and signs, and the description thereof will not be repeated.

The light-emitting layer 54 (refer to FIG. 1) according to a fourth embodiment differs from that of the light-emitting element 5 according to the first embodiment only in including a quantum dot 400 according to the fourth embodiment and the neutral ligand 3 instead of the quantum dot 100 according to the first embodiment and the polar ligand 2.

### Structure of Quantum Dot

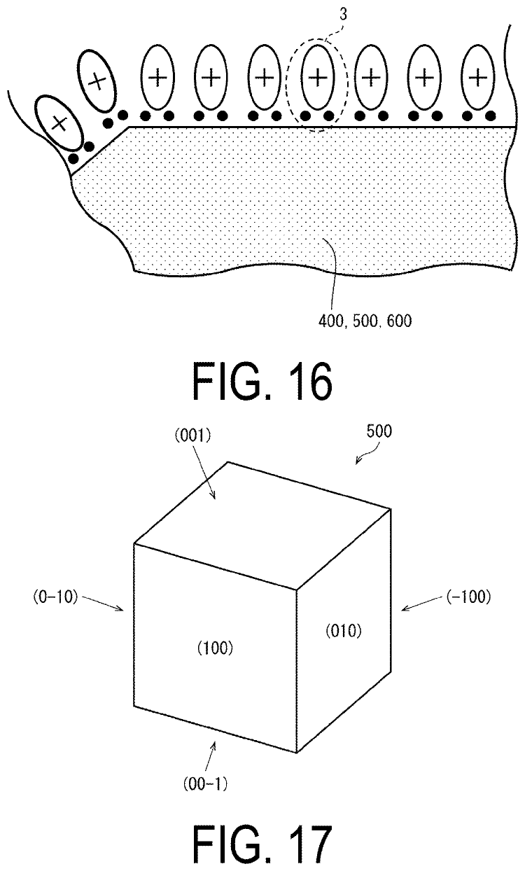

FIG. 15 is a perspective view illustrating a structure of an example of the quantum dot 400 according to this fourth embodiment. FIG. 16 is a schematic view schematically illustrating a surface of the quantum dot 400 illustrated in FIG. 15 and the neutral ligands 3 protecting the surface.

The quantum dot 400 according to the fourth embodiment has a zinc-blende crystal system. The quantum dot 400 preferably includes at least one material selected from the group consisting of those that can spontaneously form a zinc-blende crystal system. Examples of the material include a group II-VI compound such as ZnS, CdSe, or ZnSe, and a group III-V compound such as InP.

In a case in which the quantum dot 400 according to the fourth embodiment has a core-shell structure, a band gap of the core is preferably smaller than a band gap of the shell, as in the first embodiment described above.

The quantum dot 400 is a polyhedral crystal including a plurality of crystal planes, and a surface thereof is mainly constituted by of non-polar planes. The surface of the quantum dot 400 includes, for example, twelve planes consisting of a (110) plane, a (011) plane, a (101) plane, a (1−10) plane, a (01−1) plane, a (−101) plane, a (−110) plane, a (0−11) plane, a (10−1) plane, a (−1−10) plane, a (0−1−1) plane, and a (−10−1) plane, each having a rhombus shape, illustrated in FIG. 15. In this case, the ideal shape of the quantum dot 400 is a dodecahedron. Of the crystal planes of the quantum dot 400, planes equivalent to the (110) plane are the (011) plane, the (101) plane, the (1−10) plane, the (01−1) plane, the (−101) plane, the (−110) plane, the (0−11) plane, the (10−1) plane, the (−1−10) plane, the (0−1−1) plane, and the (−10−1) plane.

The (110) equivalent planes in the zinc-blende crystal system are non-polar planes. When the surface of the quantum dot 400 is constituted by non-polar planes, the surface of the quantum dot 400 can be sufficiently protected (surface-protected) by only using the neutral ligands 3, as illustrated in FIG. 16. The neutral ligand 3 can bind to a non-polar plane via an unshared electron pair 3a.

In a case in which 70% or more of the surface of the quantum dot 400 according to the fourth embodiment are non-polar planes, the surface of the quantum dot 400 can be sufficiently protected (surface-protected) by using only the neutral ligands 3 for reasons similar to those of the first embodiment described above.

As the area percentage of the non-polar planes of the surface of the quantum dot 400 increases, the effect of surface protection by the neutral ligands 3 improves. Therefore, the surface of the quantum dot 400 according to the fourth embodiment, conversely to the first embodiment described above, need only include non-polar planes accounting for an area percentage of 70% or more, preferably 80% or more, and more preferably 90% or more. Further, ideally the surface of the quantum dot 400 includes non-polar planes only.

As in the first embodiment described above, if the calculated area percentage of non-polar planes in the crystal plane analysis result of the quantum dot 400 is 60% or more, at least some of the quantum dots 400 included in the light-emitting layer 54 are regarded as sufficiently surface-protected by the neutral ligands 3 alone. If the percentage is 90% or more, the light-emitting layer 54 is regarded as including the quantum dot 400 with non-polar planes accounting for 100% of the surface.

A non-polar plane has a low surface charge and a low dangling bond density compared to those of a polar plane. For this reason, a non-polar plane tends to have relatively low reactivity and, when the ligands are desorbed from the surface of the quantum dot, tends to be relatively unlikely to react with impurities or the like. Accordingly, the quantum dot 400 according to the fourth embodiment is less likely to deteriorate, making it possible to improve the reliability of the light-emitting layer 54 and the light-emitting element 5.

The neutral ligand 3 is organic, and includes, for example, at least one type selected from the group consisting of organic neutral ligands including one or more of a phosphine group, a phosphine oxide group, and an amine group at a terminal. The ligand including a phosphine group at a terminal partially includes a structure represented by the following structural formula (8) or the following structural formula (9). The ligand including a phosphine oxide group at a terminal partially includes a structure represented by the following structural formula (10). The ligand including an amine group at a terminal partially includes a structure represented by any one of the following structural formulae (11) to (15).

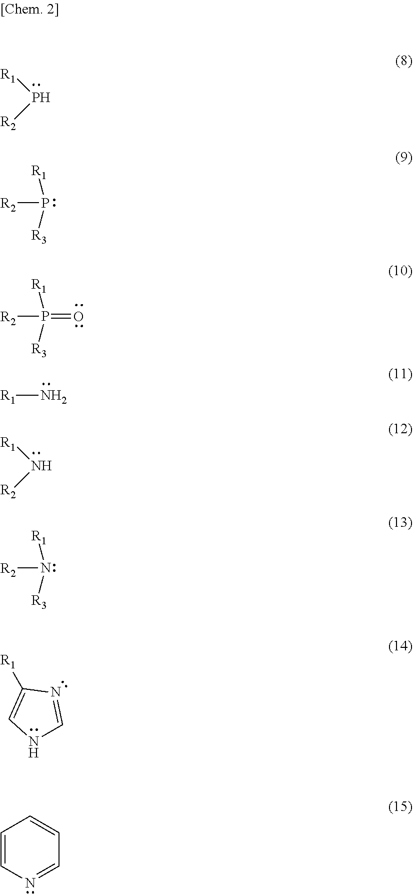

Note that, in the structural formulae (8) to (15), H represents a hydrogen atom, N represents a nitrogen atom, O represents an oxygen atom, P represents a phosphorus atom, and R₁, R₂, and R₃ each independently represent a hydrogen atom, an alkyl group, an aryl group, an alkoxyl group, or an unsaturated hydrocarbon group.

### Manufacturing Method of Quantum Dot

The quantum dot 400 may be manufactured by, for example, a heating method, a hot injection method, a microwave-assisted method, or a continuous flow method, as in the first embodiment described above.

A quantum dot having a dodecahedral shape such as illustrated in FIG. 15 can be manufactured by using neutral ligands that preferentially bind to non-polar planes during synthesis of the outermost layer. For example, when the quantum dot 400 is made of CdSe, the neutral ligands are added in a relatively large amount and crystals are grown at a reaction temperature of about 250° C. The neutral ligand is preferably an amine-based ligand. The amine-based ligand binds strongly to the (110) equivalent planes of CdSe and weakly or not to other planes. As a result, crystal growth proceeds on planes other than the (110) equivalent planes, and the surface of the quantum dot 400 is constituted by the (110) equivalent planes.

The fourth embodiment can also be applied to a solar cell as in the first embodiment described above.

### Fifth Embodiment

Another embodiment of the disclosure will be described below. Note that, for convenience of description, members having the same functions as those of the members described in the above-described embodiment will be denoted by the same reference numerals and signs, and the description thereof will not be repeated.

The light-emitting layer 54 (refer to FIG. 1) according to a fifth embodiment differs from that of the light-emitting element 5 according to the first embodiment described above only in including a quantum dot 500 according to the fifth embodiment and the neutral ligand 3 instead of the quantum dot 100 according to the first embodiment described above and the polar ligand 2.

### Structure of Quantum Dot

FIG. 17 is a perspective view illustrating a structure of an example of the quantum dot 500 according to this fifth embodiment.

The quantum dot 500 according to the fifth embodiment has a sodium chloride crystal system. The quantum dot 500 preferably includes at least one material selected from the group consisting of those that can spontaneously form a sodium chloride crystal system. The material is, for example, a group IV-VI compound such as PbTe, PbSe, or PbS.

When the quantum dot 500 according to the fifth embodiment has a core-shell structure, a band gap of the core is preferably smaller than a band gap of the shell, as in the first embodiment described above.

The quantum dot 500 is a polyhedral crystal including a plurality of crystal planes, and the surface thereof is mainly constituted by non-polar planes. The surface of the quantum dot 500 includes, for example, six planes consisting of a (100) equivalent plane, a (−100) plane, a (010) plane, a (0−10) plane, a (001) plane, and a (00−1) plane, each having a quadrangular shape, illustrated in FIG. 17. These six planes are (100) equivalent planes. In this case, the ideal shape of the quantum dot 500 is a cuboid.

The (100) equivalent planes in a sodium chloride crystal system are non-polar planes. The surface of the quantum dot 500 according to the fifth embodiment, as in the fourth embodiment described above, need only include non-polar planes accounting for an area percentage of 70% or more, preferably 80% or more, and more preferably 90% or more. Further, ideally the surface of the quantum dot 500 includes non-polar planes only.

As in the first embodiment described above, if the calculated area percentage of the non-polar planes in the crystal plane analysis result of the quantum dot 500 is 90% or more, the light-emitting layer 54 is regarded as including the quantum dot 500 with non-polar planes accounting for 100% of the surface.

### Manufacturing Method of Quantum Dot

The quantum dot 500 according to the fifth embodiment may be manufactured by, for example, a heating method, a hot injection method, a microwave-assisted method, or a continuous flow method, as in the first embodiment described above.

In addition to the manufacturing method described in NPL 1, the quantum dot 500 having a hexahedral shape such as illustrated in FIG. 17 can be manufactured by using neutral ligands (amine-based ligands) that preferentially bond to non-polar planes during synthesis of the outermost layer to lower the reaction temperature. For example, when the quantum dot 100 is made of PbS, crystals are grown at about 110° C.

The fifth embodiment can also be applied to a solar cell as in the first embodiment described above.

### Sixth Embodiment

Another embodiment of the disclosure will be described below. Note that, for convenience of description, members having the same functions as those of the members described in the above-described embodiment will be denoted by the same reference numerals and signs, and the description thereof will not be repeated.

The light-emitting element 5 (refer to FIG. 1) according to a sixth embodiment differs from the light-emitting element 5 according to the first embodiment described above only in that the light-emitting layer 54 includes a quantum dot 600 according to the sixth embodiment and the neutral ligand 3 instead of the quantum dot 100 according to the first embodiment described above and the polar ligand 2.

### Structure of Quantum Dot

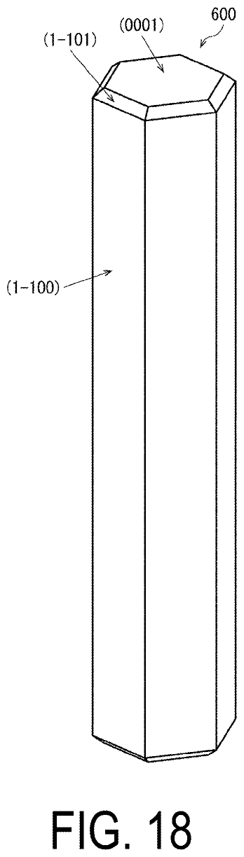

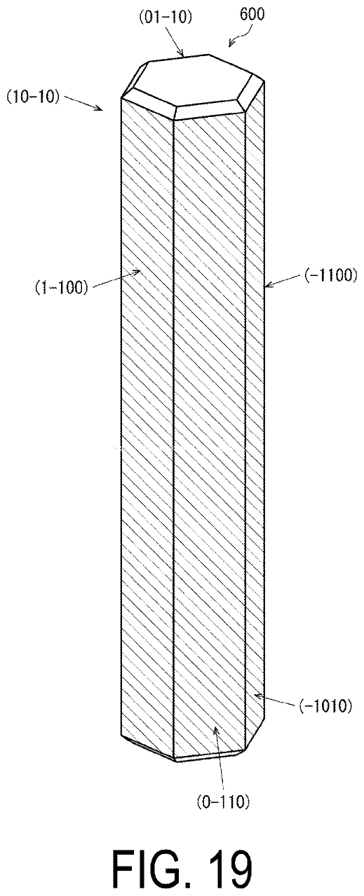

FIG. 18 is a perspective view illustrating a structure of an example of the quantum dot 600 according to this sixth embodiment. FIG. 19 is a view illustrating a plane orientation of each crystal plane of the quantum dot 600 illustrated in FIG. 18.

The quantum dot 600 according to the sixth embodiment has a wurtzite crystal system. The quantum dot 600 preferably includes at least one material selected from the group consisting of those that can spontaneously form a wurtzite crystal system. The material is, for example, a group II-VI compound such as ZnS, CdSe, or ZnSe. Note that the group II-VI compound may have a zinc-blende crystal system, depending on crystal growth conditions.

The quantum dot 600 is a polyhedral crystal including a plurality of crystal planes, and a surface thereof is mainly constituted by polar planes. The quantum dot 600 has, for example, a rod shape elongated in the [0001] direction and including, as side surfaces, six planes consisting of a (1−100) plane, a (0−110) plane, a (−1010) plane, a (−1100) plane, a (01−10) plane, and a (10−10) plane, each having a rectangular shape, illustrated in FIG. 19. The shape of the rod includes a hexagonal column shape and a shape obtained by cutting one or more corners of the hexagonal column.

FIG. 19 is a view illustrating the (1−100) plane and equivalent planes of the crystal planes of the quantum dot 600. In FIG. 19, the (1−100) plane and the planes equivalent to the (1−100) plane are shaded. Of the crystal planes of the quantum dot 600, the planes equivalent to the (1−100) plane are the (0−110) plane, the (−1010) plane, the (−1100) plane, the (01−10) plane, and the (10−10) plane.

The (−1100) equivalent planes in the wurtzite crystal are non-polar planes. The surface of the quantum dot 600 according to the sixth embodiment, as in the fourth embodiment described above, need only include non-polar planes accounting for an area percentage of 70% or more, preferably 80% or more, and more preferably 90% or more. Further, ideally the surface of the quantum dot 600 includes non-polar planes only.

As in the first embodiment described above, if the calculated area percentage of non-polar planes in the crystal plane analysis result of the quantum dot 600 is 90% or more, the light-emitting layer 54 is regarded as including the quantum dot 600 with non-polar planes accounting for 100% of the surface of the quantum dot 600.

In the quantum dot 600, a plane between first sides of the side surfaces and a plane between second sides of the side surfaces may be polar planes, and may include, for example, a (0001) equivalent plane and/or a (1−101) equivalent plane.

As illustrated in FIG. 18, because the percentage of the area of the (−1100) equivalent planes to the surface of the quantum dot 600 is large, the quantum dot 600 has a rod-like shape elongated in the [0001] direction. Therefore, the direction of recombination of the excitons in the quantum dot 600 is mainly a direction substantially parallel to the [0001] direction. As a result, light emitted by recombination of the excitons is strongly emitted in a direction substantially orthogonal to the [0001] direction of the quantum dot 600. At the time of formation of the light-emitting layer 54, the quantum dot 600 is likely to be deposited such that any one of the (−1100) equivalent planes of the quantum dot 600 is positioned on the upper face side or the bottom face side of the light-emitting layer 54 due to its own weight. As a result, in the light-emitting element 5, the light-emitting layer 54 emits light mainly in a direction substantially orthogonal to the upper face and the bottom face of the light-emitting layer 54. Therefore, reflection of the emitted light by the boundary surface of the light-emitting element 5 is unlikely, reducing the attenuation of the light inside the light-emitting element 5. In this way, the efficiency at which light is extracted from the light-emitting element 5 is improved.

### Manufacturing Method of Quantum Dot

The quantum dot 600 according to the sixth embodiment may be manufactured by, for example, a heating method, a hot injection method, a microwave-assisted method, or a continuous flow method, as in the first embodiment described above.

The rod-shaped wurtzite quantum dot illustrated in FIG. 18 can be manufactured by forming a wurtzite nanocrystal as a core and epitaxially growing a wurtzite-type nanocrystal as a shell on the (0001) equivalent planes of the core.

For example, in a case in which the quantum dot 600 includes a core of CdSe and a shell of CdS, first, a three-necked flask is prepared and 1.5 mmol of CdO, 6 mmol of n-tetradecylphosphonic acid (TDPA), 24 mmol of oleyl alcohol, and 10 g of TOPO are added to the three-necked flask and mixed. This is heated at 150° C. for 1 hour in a nitrogen atmosphere. Subsequently, the temperature is increased to 350° C. and, at the moment when this solution becomes transparent, 2 ml of TOP are injected into the flask. When this solution reaches a temperature of 350° C., 1.5 ml of a trioctylphosphine selenide complex (TOP-Se) solution having a volume molar concentration of 1.7 mol/l is injected into the flask. After a reaction of several seconds, the flask is immersed in 80° C. water to lower the temperature and stop the reaction. Subsequently, 20 ml of methanol is added to the solution to precipitate the nanoparticles. These nanoparticles are wurtzite crystals of CdSe. The CdSe nanocrystals are dispersed in a solution of trioctylphosphine sulfide (TOP-S) having a volume concentration of 2.4 mol/l.

Next, a three-necked flask is prepared, and 5 g of TOPO, a desired amount of octadecylphosphonic acid (ODPA), a desired amount of dodecylphosphonic acid (DDPA), and a desired amount of CdO are added to the flask and mixed. This is heated at 150° C. for 1 hour in a nitrogen atmosphere. Subsequently, the temperature is increased to 350° C. and, at the moment when the solution becomes transparent, 1 ml of TOP is injected into the flask. When this solution reaches a temperature of 350° C., 2 ml of the above-described solution with the CdSe nanocrystals dispersed in the TOP-S are injected into the flask. Note that, here, the molar ratio of Cd to S is maintained at 1.2:1 and thus the cation-rich surface of the CdS crystal is readily exposed. After a reaction of a sufficient time, the flask is immersed in water at 80° C. to lower the temperature and stop the reaction. Next, 5 ml of toluene and 10 ml of methanol are added to the solution to precipitate the nano-rods. The nano-rods are the quantum dots 600.

### Modified Example

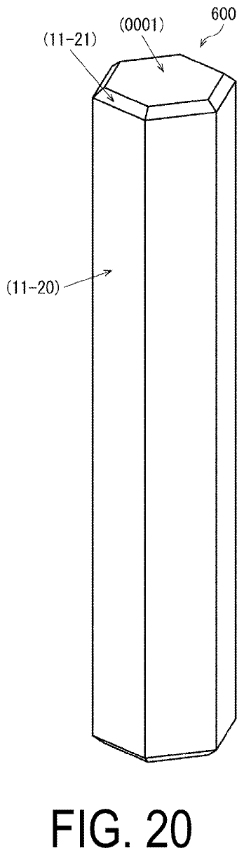

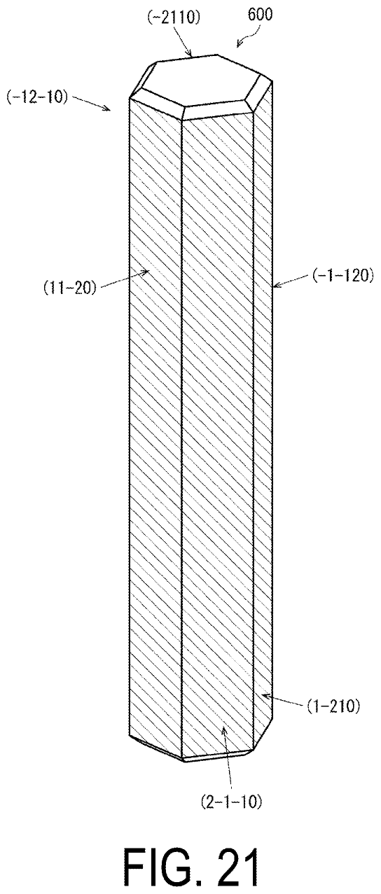

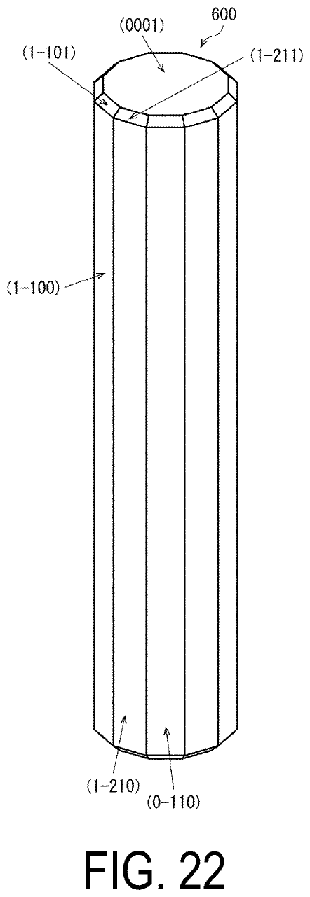

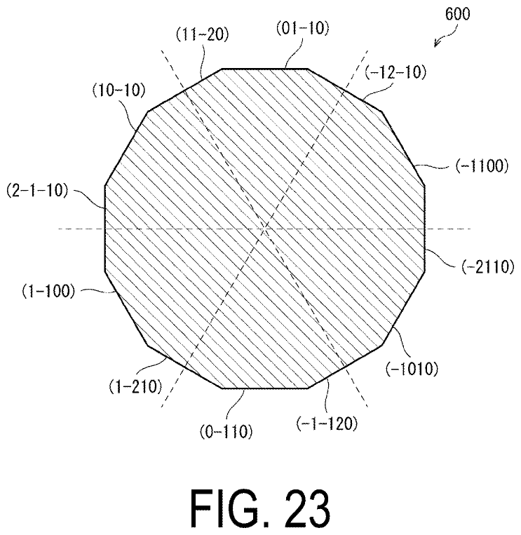

FIG. 20 and FIG. 22 are each a perspective view illustrating a structure of a modified example of the quantum dot 600 according to the sixth embodiment. FIG. 21 is a view illustrating a plane orientation of each crystal plane of the quantum dot 600 illustrated in FIG. 20. FIG. 23 is a transverse cross-sectional view illustrating a plane orientation of each crystal plane of the quantum dot 600 illustrated in FIG. 22.

The quantum dot 600 according to the sixth embodiment is not limited to that described above.

The quantum dot 600 may have, for example, an elongated rod shape including, as side surfaces, six planes consisting of a (11−20) plane, a (−2110) plane, a (1−210) plane, a (−1−120) plane, a (2−1−10) plane, and a (−12−10) plane, each have a rectangular shape, illustrated in FIG. 20 and FIG. 21. Planes equivalent to the (11−20) plane are the (−2110) plane, the (1−210) plane, the (−1−120) plane, the (2−1−10) plane, and the (−12−10) plane. In this case, in the quantum dot 600, a plane between first sides of the side surfaces and a plane between second sides of the side surfaces may include, for example, a (0001) equivalent plane and/or an (11−21) equivalent plane.

FIG. 21 is a view illustrating the (11−20) equivalent planes of the crystal planes of the quantum dot 600 illustrated in FIG. 20.

In a wurtzite crystal, the (11−20) equivalent planes are non-polar planes.

For example, as illustrated in FIG. 22, the quantum dot 600 may have a long rod shape including, as side surfaces, 12 planes consisting of (1−100) equivalent planes and (11−20) equivalent planes. In this case, the shape of the rod includes a dodecagon prism shape and a shape obtained by cutting one or more corners of the dodecagon prism. FIG. 23 is a cross-sectional view of the quantum dot 600 illustrated in FIG. 22. In this case, in the quantum dot 600, a plane between first sides of the side surfaces and a plane between second sides of the side surfaces may include, for example, a (0001) equivalent plane and/or a (1−101) equivalent plane and an (11−21) equivalent plane.

The sixth embodiment can also be applied to a solar cell as in the first embodiment described above.

### Supplement

According to a first aspect of the disclosure, a quantum dot includes a surface including polar planes accounting for an area percentage of 70% or more or a surface including non-polar planes accounting for an area percentage of 70% or more.

Note that “area percentage” in the first aspect described above is an actual value. As described above, if the area percentage of polar planes (or non-polar planes) in the analysis result is 60% or more, quantum dots with polar planes (or non-polar planes) accounting for 70% of the surface are regarded as included throughout the light-emitting layer. Therefore, when the area percentage of polar planes (or non-polar planes) in the analysis result is 60% or more, at least some of the quantum dots included in the quantum dot layer are regarded as sufficiently surface-protected by the polar ligands (or neutral ligands) alone.

According to a second aspect of the disclosure, in the quantum dot in the first aspect described above, the surface may include only polar planes or only non-polar planes.

Note that, as described above, if the area percentage of polar planes (or non-polar planes) in the analysis result is 90% or more, the quantum dot layer is actually regarded as including quantum dots with polar planes (or non-polar planes) accounting for 100% of the surface of the quantum dot.

According to a third aspect of the disclosure, in the first or second aspect described above, the quantum dot may include a core-shell structure, and a band gap of the core may be smaller than a band gap of the shell.

According to a fourth aspect of the disclosure, in any one of the first to third aspects described above, the quantum dot may include a zinc-blende crystal system, and the surface may include 14 planes consisting of a (100) plane, a (−100) plane, a (010) plane, a (0−10) plane, a (001) plane, a (00−1) plane, a (111) plane, a (−111) plane, a (1−11) plane, a (−1−11) plane, a (11−1) plane, a (−11−1) plane, a (1−1−1) plane, and a (−1−1−1) plane.

According to a fifth aspect of the disclosure, in any one of the first to third aspects, the quantum dot may include a zinc-blende crystal system, and the surface may include six planes consisting of a (100) plane, a (−100) plane, a (010) plane, a (0−10) plane, a (001) plane, and a (00−1) plane.

According to a sixth aspect of the disclosure, in any one of the first to third aspects, the quantum dot may include a zinc-blende crystal system, and the surface may include eight planes consisting of a (111) plane, a (−111) plane, a (1−11) plane, a (−1−11) plane, a (11−1) plane, a (−11−1) plane, a (1−1−1) plane, and a (−1−1−1) plane.

According to a seventh aspect of the disclosure, in any one of the first to third aspects, the quantum dot may include a sodium chloride crystal system, and the surface may include eight planes consisting of a (111) plane, a (−111) plane, a (1−11) plane, a (−1−11) plane, a (11−1) plane, a (−11−1) plane, a (1−1−1) plane, and a (−1−1−1) plane.

According to an eighth aspect of the disclosure, in any one of the first to third aspects, the quantum dot may include a wurtzite crystal system, and the surface may include two planes consisting of a (0001) plane and a (000-1) plane.

According to a ninth aspect of the disclosure, a quantum dot layer includes the quantum dot according to any one of the fourth to eighth aspects, and a polar ligand.

According to a tenth aspect of the disclosure, in the quantum dot layer in the ninth aspect, as a substance quantity percentage, the polar ligand may account for 90% or more of ligands included in the quantum dot layer.

Note that “substance quantity percentage” in the tenth aspect described above is an analysis result. As described above, if the percentage of polar ligands in the analysis result is 90% or more, the probability that, as a substance quantity percentage, 100% of the ligands actually included in the quantum dot are polar ligands is regarded as high.

According to an eleventh aspect of the disclosure, in the quantum dot layer in the ninth or tenth aspect, the polar ligand may partially have at least one structure expressed by the following structural formulae (1) to (7):

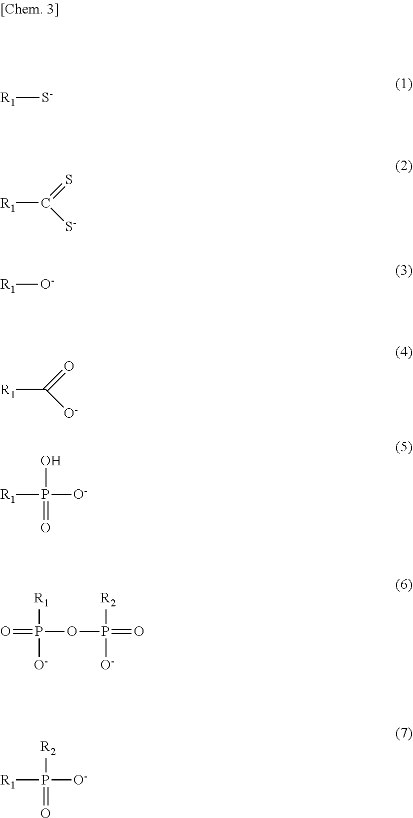

In the formulae, C represents a carbon atom, O represents an oxygen atom, O⁻ represents an oxide ion, S represents a sulfur atom, S⁻ represents a sulfide ion, P represents phosphorus, and R₁ and R₂ each independently represent a hydrogen atom, an alkyl group, an aryl group, an alkoxyl group, or an unsaturated hydrocarbon group.

According to a twelfth aspect of the disclosure, in the quantum dot layer according to the ninth or tenth aspect, the polar ligand may include at least one type selected from the group consisting of inorganic polar ligands represented by ionic Cl⁻, Br, I⁻, SCN⁻, CN⁻, OH⁻, SH⁻, SeH⁻, TeH⁻, Se²⁻ S²⁻, Te²⁻, Sn₂S₆⁴⁻, Sn₂Se₆⁴⁻, In₂Se₄²⁻, In₂Te₄²⁻, Ga₂Se₄²⁻, Sb₂Se₄²⁻, and Sb₂Te₄²⁻.

According to a thirteenth aspect of the disclosure, in any one of the first to third aspects, the quantum dot may include a zinc-blende crystal system, and the surface may include 12 planes consisting of a (101) plane, a (−101) plane, a (011) plane, a (0−11) plane, a (110) plane, a (−110) plane, a (1−1−) plane, a (−1−10) plane, a (10−1) plane, a (−10−1) plane, a (01−1) plane, and a (0−1−1) plane.

According to a fourteenth aspect of the disclosure, in any one of the first to third aspects, the quantum dot may include a sodium chloride crystal system, and the surface may include six planes consisting of a (100) plane, a (−100) plane, a (010) plane, a (0−10) plane, a (001) plane, and a (00−1) plane.

According to a fifteenth aspect of the disclosure, in any one of the first to third aspects, the quantum dot may include a wurtzite crystal system, and the surface may include 12 planes consisting of a (1−100) plane, a (0−110) plane, a (−1010) plane, a (−1100) plane, a (01−10) plane, a (10−10) plane, a (11−20) plane, a (−2110) plane, a (1−210) plane, a (−1−120) plane, a (−2−1−10) plane, and a (−12−10) plane.

According to a sixteenth aspect of the disclosure, in any one of the first to third aspects, the quantum dot may include a wurtzite crystal system, and the surface may include six planes consisting of a (1−100) plane, a (0−110) plane, a (−1010) plane, a (−1100) plane, a (01−10) plane, and a (10−10) plane.

According to a seventeenth aspect of the disclosure, in any one of the first to third aspects, the quantum dot may include a wurtzite crystal system, and the surface may include six planes consisting of a (11−20) plane, a (−2110) plane, a (1−210) plane, a (−1−120) plane, a (2−1−10) plane, and a (−12−10) plane.

According to an eighteenth aspect of the disclosure, the quantum dot layer includes the quantum dot according to any one of the thirteenth to seventeenth aspects and a neutral ligand.

According to a nineteenth aspect of the disclosure, in the quantum dot layer in the eighteenth aspect, as a substance quantity percentage, the neutral ligand may account for 90% or more of ligands included in the quantum dot layer.

Note that “substance quantity percentage” in the nineteenth aspect described above is an analysis result. As described above, if the percentage of neutral ligands in the analysis result is 90% or more, the probability that, as a substance quantity percentage, 100% of the ligands actually included in the quantum dot are neutral ligands is regarded as high.

According to a twentieth aspect of the disclosure, in the quantum dot layer in the eighteenth or nineteenth aspect, the neutral ligand may partially have at least one structure expressed by the following structural formulae (8) to (15).

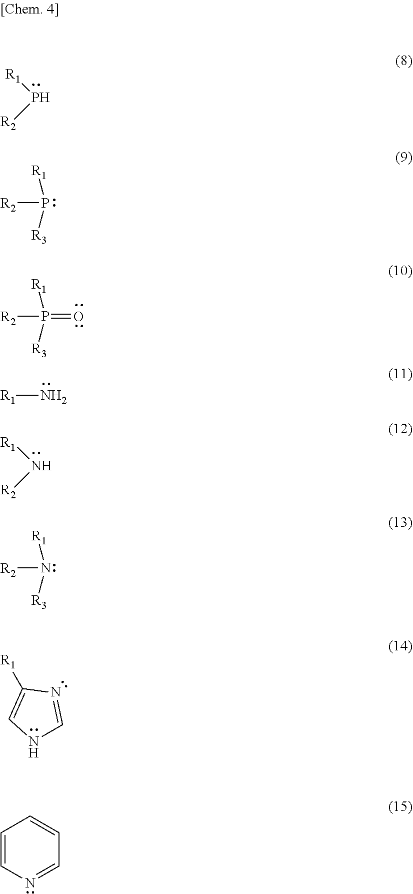

In the formulae, O represents an oxygen atom, O⁻ represents an oxide ion, P represents phosphorus, and R₁, R₂, and R₃ each independently represent a hydrogen atom, an alkyl group, an aryl group, an alkoxyl group, or an unsaturated hydrocarbon group.

According to a twenty-first aspect of the disclosure, a light-emitting element includes the quantum dot layer according to any one of the ninth to twelfth aspects and the eighteenth to twentieth aspects.

According to a twenty-second aspect of the disclosure, a solar cell includes the quantum dot layer according to any one of the ninth to twelfth aspects and the eighteenth to twentieth aspects.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A quantum dot comprising:
a surface including polar planes accounting for an area percentage of 70% or more; or
a surface including non-polar planes accounting for an area percentage of 70% or more.

2. The quantum dot according to claim 1,
wherein the surface includes only polar planes or only non-polar planes.

3. The quantum dot according to claim 1, comprising
a core-shell structure,
wherein a band gap of the core is smaller than a band gap of the shell.

4. The quantum dot according to claim 1, comprising
a zinc-blende crystal system,
wherein the surface includes 14 planes consisting of a (100) plane, a (−100) plane, a (010) plane, a (0−10) plane, a (001) plane, a (00−1) plane, a (111) plane, a (−111) plane, a (1−11) plane, a (−1−11) plane, a (11−1) plane, a (−11−1) plane, a (1−1−1) plane, and a (−1−1−1) plane.

5. The quantum dot according to claim 1, comprising
a zinc-blende crystal system,
wherein the surface includes six planes consisting of a (100) plane, a (−100) plane, a (010) plane, a (0−10) plane, a (001) plane, and a (00−1) plane.

6. The quantum dot according to claim 1, comprising
a zinc-blende crystal system,
wherein the surface includes eight planes consisting of a (111) plane, a (−111) plane, a (1−11) plane, a (−1−11) plane, a (11−1) plane, a (−11−1) plane, a (1−1−1) plane, and a (−1−1−1) plane.

7. The quantum dot according to claim 1, comprising
a sodium chloride crystal system,
wherein the surface includes eight planes consisting of a (111) plane, a (−111) plane, a (1−11) plane, a (−1−11) plane, a (11−1) plane, a (−11−1) plane, a (1−1−1) plane, and a (−1−1−1) plane.

8. The quantum dot according to claim 1, comprising
a wurtzite crystal system,
wherein the surface includes two planes consisting of a (0001) plane and a (000−1) plane.

9. A quantum dot layer comprising:
the quantum dot described in claim 4; and
a polar ligand.

10. The quantum dot layer according to claim 9,
wherein, as a substance quantity percentage, the polar ligand accounts for 90% or more of ligands included in the quantum dot layer.

11. The quantum dot layer according to claim 9,
wherein the polar ligand partially has at least one structure expressed by the following structural formulae (1) to (7): 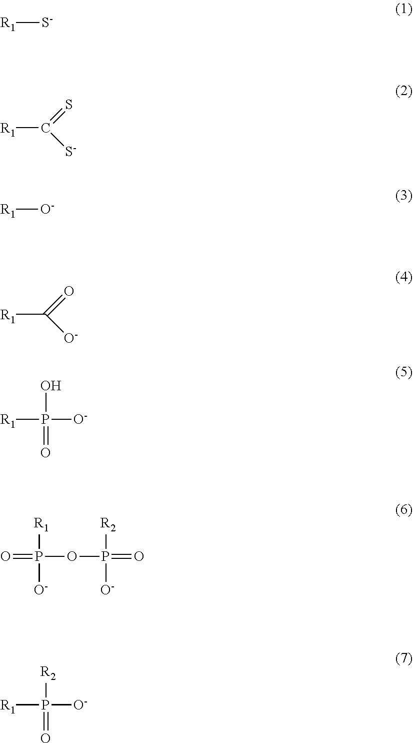
where C represents a carbon atom, O represents an oxygen atom, O⁻ represents an oxide ion, S represents a sulfur atom, S⁻ represents a sulfide ion, P represents phosphorus, and R₁ and R₂ each independently represent a hydrogen atom, an alkyl group, an aryl group, an alkoxyl group, or an unsaturated hydrocarbon group.

12. The quantum dot layer according to claim 9,
wherein the polar ligand includes at least one type selected from the group consisting of inorganic polar ligands represented by ionic Cl⁻, Br⁻, I⁻, SCN⁻, CN⁻, OH⁻, SH⁻, SeH⁻, TeH⁻, Se²⁻, S²⁻, Te²⁻, Sn₂S₆⁴⁻, Sn₂Se₆⁴⁻, In₂Se₄²⁻, In₂Te₄²⁻, Ga₂Se₄²⁻, Sb₂Se₄²⁻, and Sb₂Te₄²⁻.

13. The quantum dot according to claim 1, comprising
a zinc-blende crystal system,
wherein the surface includes 12 planes consisting of a (101) plane, a (−101) plane, a (011) plane, a (0−11) plane, a (110) plane, a (−110) plane, a (1−1−) plane, a (−1−10) plane, a (10−1) plane, a (−10−1) plane, a (01−1) plane, and a (0−1−1) plane.

14. The quantum dot according to claim 1, comprising
a sodium chloride crystal system,
wherein the surface includes six planes consisting of a (100) plane, a (−100) plane, a (010) plane, a (0−10) plane, a (001) plane, and a (00−1) plane.

15. The quantum dot according to claim 1, comprising
a wurtzite crystal system,
wherein the surface includes 12 planes consisting of a (1−100) plane, a (0−110) plane, a (−1010) plane, a (−1100) plane, a (01−10) plane, a (10−10) plane, a (11−20) plane, a (−2110) plane, a (1−210) plane, a (−1−120) plane, a (2−1−10) plane, and a (−12−10) plane.

16. The quantum dot according to claim 1, comprising
a wurtzite crystal system,
wherein the surface includes six planes consisting of a (1−100) plane, a (0−110) plane, a (−1010) plane, a (−1100) plane, a (01−10) plane, and a (10−10) plane.

17. The quantum dot according to claim 1, comprising
a wurtzite crystal system,
wherein the surface includes six planes consisting of a (11−20) plane, a (−2110) plane, a (1−210) plane, a (−1−120) plane, a (2−1−10) plane, and a (−12−10) plane.

18. A quantum dot layer comprising:
the quantum dot described in claim 13; and
a neutral ligand.

19. The quantum dot layer according to claim 18,
wherein, as a substance quantity percentage, the neutral ligand accounts for 90% or more of ligands included in the quantum dot layer.

20. The quantum dot layer according to claim 18,
wherein the neutral ligand partially has at least one structure expressed by the following structural formulae (8) to (15): 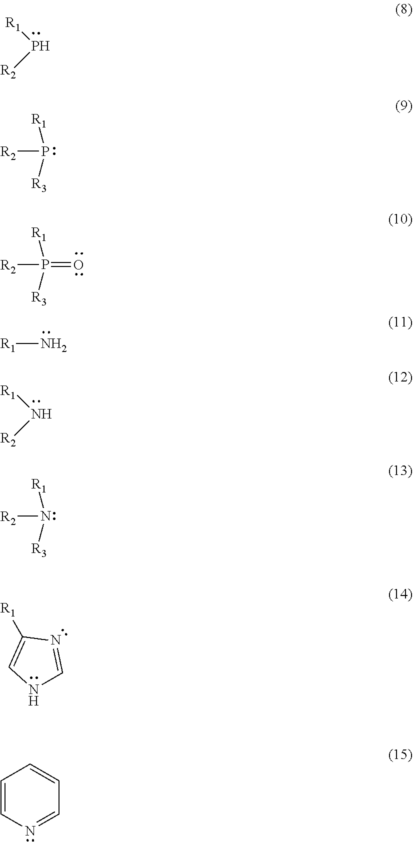
where O represents an oxygen atom, O⁻ represents an oxide ion, P represents phosphorus, and R₁, R₂, and R₃ each independently represent a hydrogen atom, an alkyl group, an aryl group, an alkoxyl group, or an unsaturated hydrocarbon group.

21. (canceled)

22. (canceled)
